(19) United States
(12) Patent Application Publication
(10) Pub. No.: US 2023/0298965 A1
(43) Pub. Date: Sep. 21, 2023

(54) Lid with Self Sealing Plug Allowing for a Thermal Interface Material with Fluidity in a Lidded Flip Chip Package

(71) Applicant: YUCI SHEN, SAN JOSE, CA (US)

(72) Inventor: YUCI SHEN, SAN JOSE, CA (US)

(21) Appl. No.: 17/831,141

(22) Filed: Jun. 2, 2022

Related U.S. Application Data
(63) Continuation-in-part of application No. 17/695,826, filed on Mar. 15, 2022.

(51) Int. Cl. H01L 23/42

(52) U.S. Cl. CPC H01L 23/42; H01L 24/16

(57) ABSTRACT

The disclosure describes a lidded flip chip package allowing for a thermal interface material (TIM) with fluidity, like a liquid metal, including: a lid, a sealing ring for forming a sealed gap between a flip chip and the lid, a storage tunnel as a reservoir for accepting or releasing a liquid metal from or to the sealed gap, and an injection tunnel for filling a liquid metal into the sealed gap, wherein a self-sealing plug structure is integrated with the storage tunnel and the injection tunnel, the sealed gap is completely filled with a liquid metal, and a portion of the storage tunnel is filled with the same liquid metal and its remaining portion is filled with a gas. The disclosure also describes a method for filling a liquid metal into the lidded flip chip package based on the self-sealing plug structure.

The present application is a continuation-in-part of U.S. patent application Ser. No. 17/695,826 filed on Mar. 15, 2022.

### TECHNICAL FIELD OF THE DISCLOSURE

The disclosure relates generally to a heat-dissipating object for dissipating heat from a heat-generating object in an electronic device, and particularly to a lid for a lidded flip chip package to use a liquid thermal interface material (TIM) or a TIM having fluidity at least during operation temperature of the lidded flip chip package.

### BACKGROUND OF THE DISCLOSURE

In a flip chip package with a semiconductor chip being a heat-generating object, a thermal interface material (TIM) is usually used to fill the gap between the flip chip and a heat-dissipating object, like a lid or a heat sink for transferring the heat from one to the other. The types of the TIM basically include thermal pad, thermal grease, phase change material and liquid metal. A good TIM needs to have 1) a high thermal conductivity, 2) a good surface wetting capability for reducing the thermal contact resistance, 3) a good gap filling capability, and 4) a good thermal reliability in test or application. A liquid metal as TIM usually includes gallium and gallium alloy. The melting point of the gallium is about 29° C., and that of gallium alloy is even lower. The thermal conductivity of the liquid metal is much higher than the extensively used thermal pad or thermal grease. Furthermore, a liquid metal has much better capability for surface wetting and gap filling. So, of all the types of TIM, a liquid metal is an ideal TIM if only looking at the first three items. If a liquid metal can be used in a lidded flip chip package, the temperature of the lidded flip chip package can be reduced significantly as compared to other types of TIM. However, the conventional lidded flip chip packages based on a conventional lid of prior arts are limited to use a liquid metal as its TIM due to the pumping-out issue, that is, when the package is under a thermal cycling test or in its long term of application, the volume of the gap between the flip chip and the lid varies with temperature due to the warpage of the flip chip, causing the liquid metal TIM to be pumped out. The TIM pumping-out issue will cause an incomplete gap filling between the flip chip and the lid, reducing the thermal performance of TIM. More importantly, because liquid metal is electrically conductive, a small amount of TIM pumping-out may damage the whole electronic device. As a result, a liquid metal type of TIM has not been commercially used in a lidded flip chip package. In general, because of similar reasons, a liquid metal type of TIM is rarely interposed between a heat-dissipating object (a heat sink, for example) and a heat-generating object (a semiconductor chip, for example) in an electronic device.

For overcoming the TIM pumping-out issue for an electronic device such as a lidded flip chip package to use a liquid TIM, a lid coupled with a reservoir structure for a lidded flip chip package to use a liquid thermal interface material has been disclosed in our prior arts, U.S. Ser. No. 10/643,924 B1 and application No. U.S. Ser. No. 17/686,372. However, the lid and the lidded flip chip package of the prior arts still have two disadvantages in its test and application. One is that a preferred liquid metal TIM, including gallium or its alloys, will oxidize when exposed to oxygen in an ambient of the lid and its lidded flip chip package of the prior arts. The liquid metal oxides formed from oxidation may accumulate with time to affect the flow of the liquid metal in the tunnel of the lid. Another disadvantage is that when a tunnel is formed by using an adhesive tape to bond a covering piece over a notch, the flow of the liquid metal in the tunnel is not very good. As a result, the sealed gap between the lid and the flip chip may become incompletely filled with the liquid metal. To eliminate the disadvantages, a lid and its lidded flip chip package are described in the present disclosure.

### SUMMARY OF THE DISCLOSURE

A lid allowing for a thermal interface material with fluidity in a lidded flip chip package, comprising: a top piece with an upper side and a lower side, a foot at the lower side of the top piece, and a reservoir structure including a storage tunnel, an injection hole, and a sealing ring; wherein the sealing ring is mounted at the lower side of the top piece, which seals a peripheral edge region at a top surface of a flip chip and/or seals a peripheral region around a flip chip and at a top surface of a substrate so as to form a sealed gap between the flip chip and the top piece; wherein the lid further includes a ring-form of cavity at the upper side of its top piece, a pattern of notch formed at a bottom of the ring-form of cavity, and a covering piece mounted in the ring-form of cavity so as to cover the pattern of notch and form the storage tunnel; wherein the storage tunnel has two ends, one end of the said two ends connects to the sealed gap through a connecting hole, and a plug structure including a hole and a plug is formed at the other end of the said two ends; wherein the injection hole has two ends, one end of the said two ends connects to the sealed gap directly or through an injection tunnel, and a plug structure including a hole and a plug is formed at the other end of the said two ends; and wherein the sealed gap is completely filled with a thermal interface material having fluidity, a portion of the storage tunnel is filled with the same thermal interface material, and the remaining portion of the storage tunnel is filled with a gas.

A method for making a lidded flip chip package based on the lid of present disclosure, comprising the following major steps:
1) Prepare a lid according to a flip chip package;
2) Form a slippery skin on an inner surface of the storage tunnel;
3) Mount the lid on the substrate and over the flip chip, wherein the sealing ring is tightly compressed to seal a peripheral edge region at a top surface of the flip chip and form a sealed gap between the flip chip and the top piece of the lid;
4) Put the assembly formed in step 3 into a vacuum oven or container and set it to a vacuum condition to degas the assembly, and then fill a liquid metal through the injection hole into the sealed gap and a portion of the storage tunnel;
5) Close the injection hole by putting back its plug at the vacuum condition first, and then put a desired gas with a desired gas pressure into the vacuum oven or container to fill the remaining portion of the storage tunnel with the gas;
6) Close the storage tunnel by putting back its plug so that the gas is sealed inside the storage tunnel;
7) Mount solder balls at a bottom side of the substrate so that a lidded flip chip package is formed.

A method for making a lidded flip chip package based on the lid of present disclosure, comprising the following major steps:
1) Prepare a lid according to a flip chip package;
2) Form a slippery skin on an inner surface of the storage tunnel;
3) Attach a piece of pre-formed liquid metal pad or form a liquid metal pad at a bottom surface of the top piece and inside the sealing ring under a low temperature;
4) Clamp the lid formed in step 3 onto the flip chip package prepared in step 1 using a clamping force, wherein an adhesive is interposed between the foot of the lid and the substrate, the sealing ring is compressed to seal at a peripheral edge region at a top surface of the flip chip and form a sealed gap between the lid and flip chip, and the liquid metal pad is clamped between the lid and the flip chip and enclosed in the sealed gap;
5) Put the assembly formed in step 4 into a vacuum oven or container and set it to a vacuum condition to degas the assembly, and then raise the oven temperature above the melting point of the liquid metal and hold this temperature for a period of time until the liquid metal pad becomes molten, so that the seal ring is further compressed, the thickness of the of the sealed gap becomes thinner, the adhesive is compressed to spread between the foot and the substrate, and the molten liquid metal pad is squeezed to fill the sealed gap and a portion of the storage tunnel; and then raise the oven temperature to a curing temperature of the adhesive and hold it until the adhesive becomes cured;
6) Put a desired gas with a desired gas pressure into the vacuum oven or container to fill the remaining portion of the storage tunnel with the gas;
7) Close the storage tunnel by putting back its plug so that the gas is sealed inside the storage tunnel;
8) Mount solder balls at a bottom side of the substrate so that a lidded flip chip package is formed.

The features and advantages of the embodiments of the present disclosure will become more apparent from the detailed descriptions in conjunction with the drawings below. The drawings and associated descriptions are to illustrate the embodiments of the present disclosure, not to limit the scope of what is claimed.

### BRIEF DESCRIPTION OF THE DRAWINGS

FIG. 1 to FIG. 3 are schematic diagrams for illustrating a lid allowing for a lidded flip chip package to use a thermal interface material with fluidity of one preferred embodiment of the present disclosure.

FIG. 4 and FIG. 4A are schematic diagrams for illustrating another plug structure for a storage tunnel, a thermally conductive mesh in the sealed gap as an option, and a foam block as a safety measure adjacent to the adhesive of a lid allowing for a lidded flip chip package to use a thermal interface material with fluidity of one embodiment of the present disclosure.

FIG. 5 to FIG. 5B are schematic diagrams for illustrating a preferred design for an injection hole of a lid allowing for a thermal interface material with fluidity in a lidded flip chip package of another preferred embodiment of the present disclosure.

FIG. 6 is a schematic diagram for illustrating a preferred design for a plug structure for opening or closing a storage tunnel or an injection hole of a lid allowing for a lidded flip chip package to use a thermal interface material with fluidity of one preferred embodiment of the present disclosure.

FIG. 7 and FIG. 8 are schematic diagrams for illustrating a foot structure being used as a sealing ring of a lid allowing for a lidded flip chip package to use a thermal interface material with fluidity of one preferred embodiment of the present disclosure.

FIG. 9 to FIG. 12 are schematic diagrams for illustrating a method for making a lidded flip chip package based on a lid of one preferred embodiment of the present disclosure.

FIG. 13 to FIG. 17 are schematic diagrams for illustrating a method for making a lidded flip chip package based on a lid of another preferred embodiment of the present disclosure.

FIG. 18, FIG. 18A, and FIG. 19 are schematic diagrams for illustrating a self-sealing plug structure integrated with a tunnel for filling and sealing a liquid metal in a lidded flip chip package to form a liquid metal thermal interface material of one preferred embodiment of the present disclosure.

FIG. 20 to FIG. 29 are schematic diagrams for illustrating a method for filling a liquid metal into the sealed gap and a portion of the storage tunnel, and for filling a desired gas with a desired gas pressure, like an inert gas with a half of the atmosphere air pressure, into the remaining portion of the storage tunnel to form a lidded flip chip package with a liquid metal TIM based on the present self-sealing plug structure of another preferred embodiment of the present disclosure.

FIG. 30 to FIG. 34 are schematic diagrams for illustrating a plurality of guiding lines introduced into the sealed gap to better fill a liquid metal into the sealed gap to form a lidded flip chip package with a liquid metal TIM of another preferred embodiment of the present disclosure.

### DETAILED DESCRIPTION OF THE PREFERRED EMBODIMENT

The present disclosure is to eliminate the disadvantages of the prior arts mentioned previously by introducing a plug structure at an end of a storage tunnel and a slippery skin on an inner surface of the storage tunnel of a lid for a lidded flip chip package, which is described in conjunction with the drawings in the following.

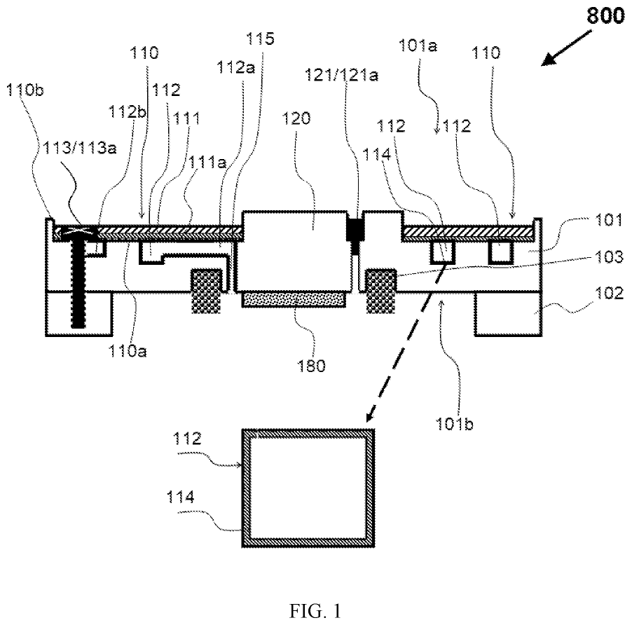

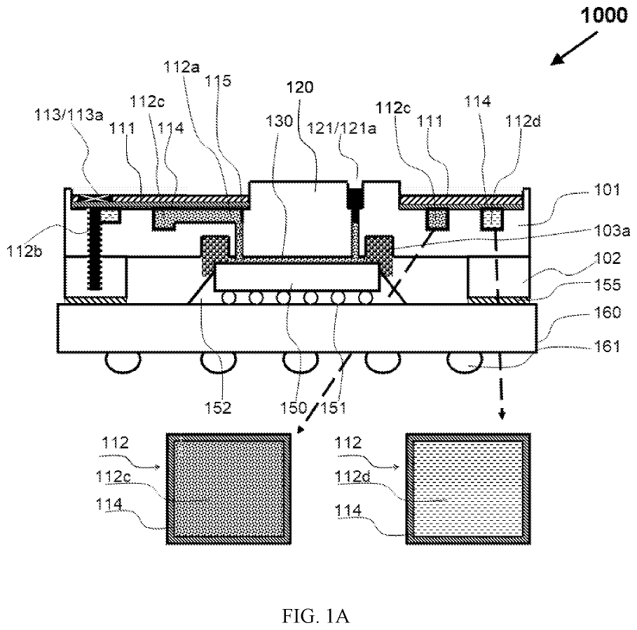

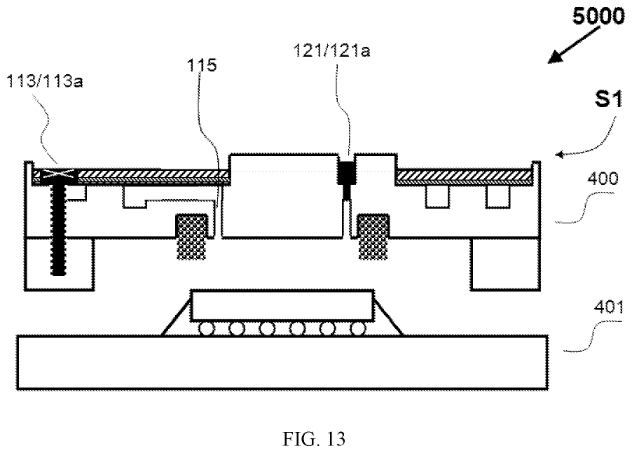

FIG. 1 and FIG. 1A are schematic diagrams for illustrating a lid allowing for a thermal interface material with fluidity in a lidded flip chip package of one preferred embodiment of the present disclosure. The numerical symbol 800 in FIG. 1 designates a cross-sectional view of a lid, in which the numerical symbol 101 designates a top piece with an upper side 101a and a lower side 101b, the 102 designates a foot at the lower side 101b of the top piece 101, the 112 designates a storage tunnel as a reservoir for accepting or releasing a liquid, the 121/121a designates an injection hole 121 with a plug 121a as a plug structure, and the 103 designates a sealing ring; wherein the sealing ring 103 is mounted at the lower side 101b of the top piece 101; wherein the lid 800 further includes a ring-form of cavity 110 at the upper side 101a of its top piece 101, a pattern of notch 112 (which uses the same numerical number 112 as that for the storage tunnel) formed at a bottom 110a of the ring-form of cavity 110, and a covering piece 111 mounted in the ring-form of cavity for covering the pattern of notch 112 so as to form the storage tunnel 112; wherein the storage tunnel 112 has two ends 112a and 112b, one end 112a connects to a bottom surface of the top piece 101 at its lower side 101b and inside the sealing ring 103 through a connecting hole 115, and a plug structure 113/113a including a hole 113 and a plug 113a is formed at the other end 112b of the storage tunnel 112 for opening or closing it to or from an outside of the lid or an ambient, like the atmosphere outside the lid; wherein the lid further includes a slippery skin 114 formed on an inner surface of the storage tunnel 112, which can be made of either a lubricant oil or some other kind of coating, as showed by the enlarged cross-sectional view of the storage tunnel 112 that the dashed arrow points to; and wherein the injection hole 121 is formed through the top piece 101 and connects to a bottom surface at its lower side 101b and inside the sealing ring 103. The numerical symbol 120 in FIG. 1 designates an island portion of the top piece 101 surrounded by the ring-form cavity 110, which is directly above a flip chip when the lid is mounted with a flip chip package as illustrated in FIG. 1A in the following. The 110b in FIG. 1 designates a rim of the ring-form cavity 110. The numerical symbol 180 in FIG. 1 designates a piece of pre-formed liquid metal pad in a solid state mounted on a bottom surface at the lower side of the top piece 101 and inside the sealing ring 103, which is optionally used to form a liquid metal thermal interface material when the lid is mounted with a flip chip package as illustrated in FIG. 13 to FIG. 17 below for a method for making a lidded flip chip package with a liquid metal thermal interface material of one embodiment of the present disclosure. It is noted that the numerical symbol 111a in FIG. 1 designates an adhesive layer as an option for bonding the covering piece 111 to the ring-form cavity in order to cover the pattern of notch 112. If a metal to metal welding is used to mount a metal covering piece 111 in the ring-form cavity for covering a pattern of notch 112, the adhesive layer 111a can be avoided.

FIG. 1A is a schematic diagram for illustrating a lidded flip chip package based on the lid described previously in conjunction with the drawing in FIG. 1 of one preferred embodiment of the present disclosure. It is noted that the same elements in a following drawing will share the same numerical symbols as described in a previous drawing, which may not be repeatedly described in the following drawing for simplicity and clearness, and the descriptions in the previous drawing should be referred to when needed. The numerical symbol 1000 in FIG. 1A designates a cross-sectional view of a lidded flip chip package based on the lid as described in FIG. 1, in which the numerical symbol 150 designates a flip chip mounted on a substrate 160 through a plurality of bumps 151 and an underfill material 152, the numerical symbol 155 designates an adhesive interposed between the foot 102 and the substrate 160 for mounting the lid 800 as described in FIG. 1 on a peripheral region of the substrate 160 and over the flip chip 150, the numerical symbol 103a designates the sealing ring 103 as described in FIG. 1, which is compressed so as to seal a peripheral edge region at a top surface of the flip chip 150 and form a sealed gap 130 between the flip chip 150 and the top piece 101, the numerical symbol 115 designates a connecting hole which connects the storage tunnel 112 as described in FIG. 1 with the sealed gap 130, the numerical symbol 130 also designates a thermal interface material having fluidity, like a liquid metal, completely filled in the sealed gap 130, the numerical symbols 112a and 112b designate two ends of the storage tunnel 112 as described in FIG. 1, and the 112c and 112d designate two portions of the storage tunnel 112, a portion 112c is filled with the same thermal interface material having fluidity, and the remaining portion 112d is filled with a gas, the 112c and 112d also designate the thermal interface material having fluidity and the gas filled in the two portions, respectively, the 121 designates an injection hole which is closed by a plug 121a after the thermal interface material having fluidity is formed in the sealed gap 130 and the portion of the storage tunnel 112c, and the 113/113a designates a plug structure at an outer end 112b of the storage tunnel 112, which is closed as an option in the application of the lidded flip chip package so that a desired gas with a desired pressure can be set in the remaining portion 112d of the storage tunnel 112.

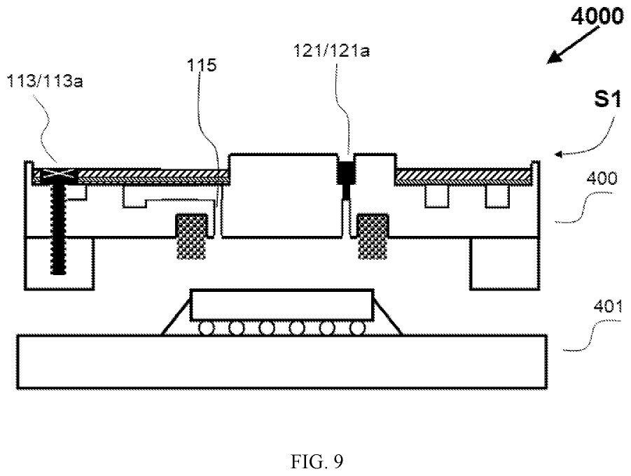

It is noted that the liquid metal gallium or its alloys are preferred to be a thermal interface material having fluidity of a lidded flip chip package of one preferred embodiment of the present disclosure. However, gallium or its alloys will quickly oxidize when exposed to oxygen or air. Because the liquid metal will move forwards or backwards between the storage tunnel 112 and the sealed gap 130, a liquid metal oxide formed from continuous oxidation will accumulate with time if the outer end 112b of the storage tunnel 112 is not isolated from air in the atmosphere. As a result, it will become difficult for the liquid metal to flow in the storage tunnel 112. To solve the oxidation issue, a plug structure like the screw hole 113 with the screw 113a is formed at the end 112b of the storage tunnel 112 so that a desired gas 112d, like an inert gas including nitrogen or helium, with a desired gas pressure can be formed in the remaining portion of the storage tunnel 112d. The plug structure can be used to open or close the end 112b of the storage tunnel 112 when needed, which will be further explained in conjunction with the drawings in FIG. 9 to FIG. 17 below. It is also noted that the gas used in the remaining portion of the storage tunnel 112d is not limited to an inert gas. When air is used as the gas in the remaining portion 112d of the storage tunnel 112, there will be some oxidation, but the oxidation will stop when the oxygen inside the storage tube is used up. In addition, to improve the flow of the liquid metal in the storage tube, a slippery skin 114 as an option is formed on an inner surface of the storage tunnel 112, and a method to form a slippery skin on an inner surface of the storage tunnel 112 and to arrange a desired gas with a desired gas pressure in the remaining portion of the storage tunnel 112d will be illustrated in conjunction with drawings in FIG. 9 to FIG. 17 below, where a method for making a lidded flip chip package based on a lid of one preferred embodiment of the present disclosure is described.

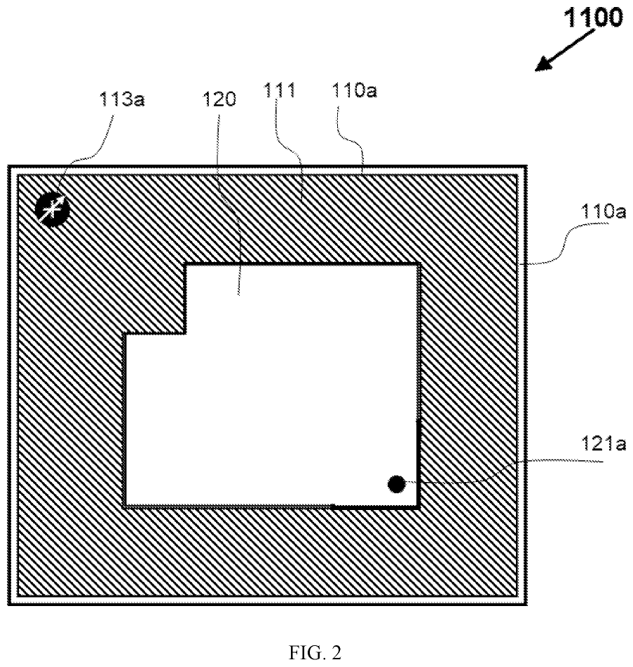

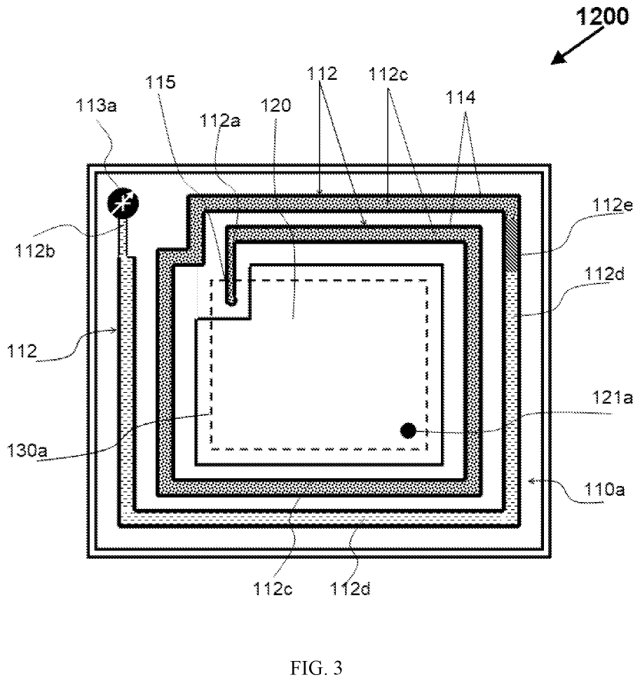

FIG. 2 and FIG. 3 are schematic diagrams for further illustrating the lidded flip chip package 1000 as shown in FIG. 1A from its top view. It is noted that the same numerical symbol will be used to designate the same element in both cross-sectional view and top view. The numerical symbol 1100 in FIG. 2 designates a top view of the lidded flip chip package as described in FIG. 1A, in which the numerical symbols 120 and 110b designate a top view of the island portion 120 and the rim 110b of the top piece 101 as shown in FIG. 1 or FIG. 1A, the ring-form cavity 110 as shown in FIG. 1 is formed between the island portion 120 and the rim 110b, the 111 designates a top view of the covering piece 111 in FIG. 1 or FIG. 1A, which is mounted in the ring-form cavity 110, and the numerical symbols 121a and 113a respectively designate a top view of the plug 121a and the plug 113a as shown in FIG. 1 or FIG. 1A. It is noted that the covering piece does not have to be a single layer, and can also be a plurality of layers of foils that are bonded together with adhesive or metal bonded. The numerical symbol 1200 in FIG. 3 designates a top view of the lidded flip chip package as described in FIG. 1A, where the covering piece 111 as shown in FIG. 2 is removed to better display the structure of the storage tunnel 112, a thermal interface material with fluidity 112c, like a liquid metal, and a gas 112d in the storage tunnel 112. The numerical symbols 112 and 114 in FIG. 3 respectively designate a top view of the storage tunnel 112 (which is a pattern of notch in the ring-form cavity 110 after the covering piece 111 is removed) and the slippery skin 114 on an inner surface of the storage tunnel 112 as shown in FIG. 1 or FIG. 1A, the 112a and the 112b in FIG. 3 designate a top view of the two ends of the storage tunnel 112, the end 112a, called an inner end, is connected to the sealed gap 130 through the connecting hole 115, the end 112b, called an outer end, is coupled with the plug structure 113/113a for opening or closing the storage tunnel 112 to/from an outside environment, like air in outside atmosphere or an inert gas in an oven or container, the 112c and the 112d in FIG. 3 respectively designate a top view of the thermal interface material having fluidity 112c, like a liquid metal in a portion of the storage tunnel 112 and the gas 112d in the remaining portion of the storage tunnel 112 as shown in FIG. 1A. The numerical symbols 121a designates a top view of the plug 121a in the injection hole 121 as shown in FIG. 1 or FIG. 1A. The dashed rectangle designated by the numerical symbol 130a in FIG. 3 displays the region of the sealed gap 130 as shown in FIG. 1A from its top view, which can be viewed as a reference to understand the relative locations among the elements in the lidded flip chip package 1000. The numerical symbol 112e designates a small amount of protecting liquid as an option, like a lubricant oil, positioned at an outer end of the liquid metal to avoid it from directly contacting with the gas 112d so as to improve the flow of the liquid metal in the storage tunnel from one side and to avoid the oxidation of the liquid metal if air is used as the gas from the other side.

It is noted that the pattern and dimension of the storage tunnel 112 can be flexibly designed according to a specific application for a specific flip chip package. Some basic considerations to design the storage tunnel 112 include: 1) its volume needs to be big enough to accommodate the volume change of the sealed gap 130, which can be very big. For example, the maximum volume of the sealed gap may be double that of its minimum volume due to a warpage behavior of the flip chip 150 during a large temperature range, like −40° C. to 245° C.; 2) A division of the storage tunnel 112 as a portion 112c for liquid metal and another portion 112d for a gas needs to be carefully determined so that the sealed gap can be completely filled with the liquid metal all the time; and 3) a safe and easy plug structure 113/113a or 121/121a for the storage tunnel 112 or the injection hole is important, which will be further described below.

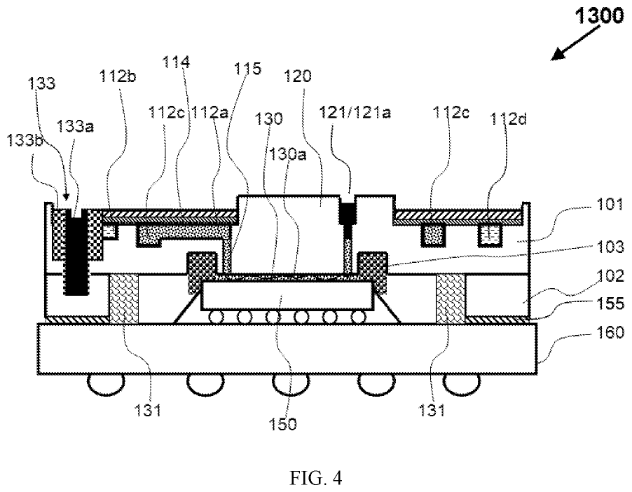

FIG. 4 and FIG. 4A are schematic diagrams for illustrating some further features including another design for a plug structure and a filter block as a safety measure of a lidded flip chip package of one preferred embodiment of the present disclosure. The numerical symbol 1300 in FIG. 4 designates a cross-sectional view of a lidded flip chip package, in which the numerical symbols 133, 133a and 133b designate another design for a plug structure, which includes a step hole 133, a headless screw 133a and a rubber tube 133b, wherein the rubber tube 133b is pushed out by the headless screw 133 to close the end 112a of the storage tunnel 112 when the headless screw 133 is driven into a small central hole of the rubber tube 133b. The numerical symbol 131 designates a filter block arranged adjacent to any openings at the adhesive 155 so that if a liquid metal would leak out from the sealed gap 130 into the cavity around the flip chip, the liquid metal would not easily flow out from the openings to the outside of the lid. The numerical symbol 130a designates a thermally conductive mesh in the sealed gap as an option. This mesh helps control the thickness of the gap as well as improves the thermal performance of the package. The numerical symbol 1400 in FIG. 4A designates a top view of the adhesive 155 and the filter block 131 as shown in FIG. 4, in which the 155a and 155b designates two example openings at the adhesive 155, and the 131a and 131b designates two filter blocks arranged adjacent to the openings. It is known that the adhesive 155 is usually not a closed loop so that the cavity around the flip chip 150 and between the lid and the substrate is not sealed. Otherwise, the air in the cavity may cause reliability issues due to a high pressure at a high temperature. The filter block 131 can also be a ring along the inner side of the adhesive, which can be flexibly designed depending on a specific application. Materials for the filter block 131 can include rubber foam, porous metal, or fiberglass mesh, which allow air in/out but does not allow a liquid metal in/out very easily.

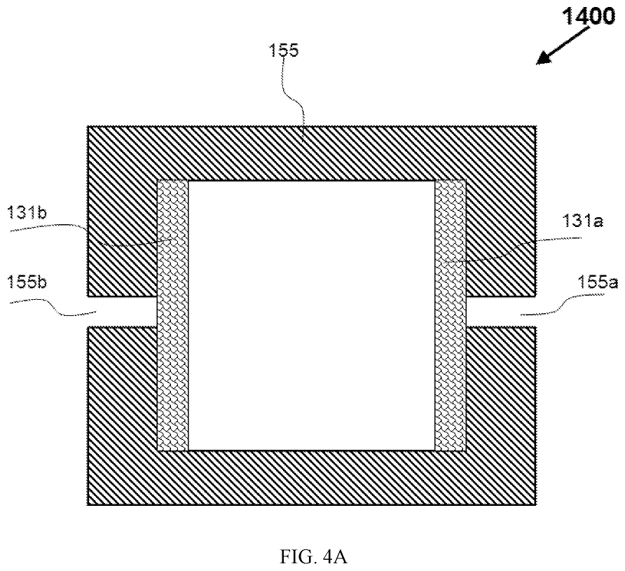

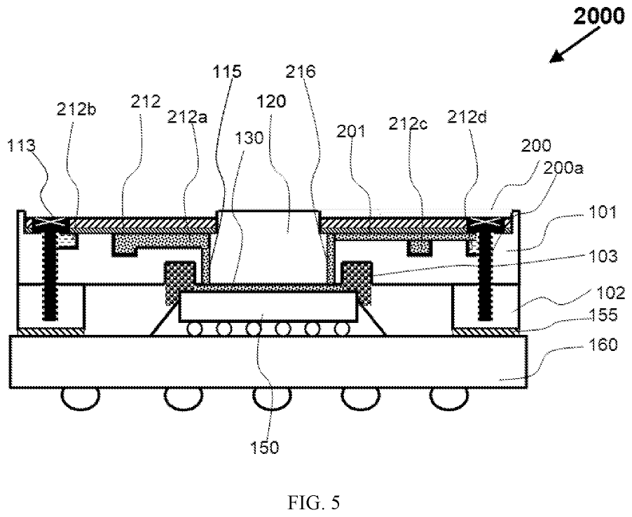

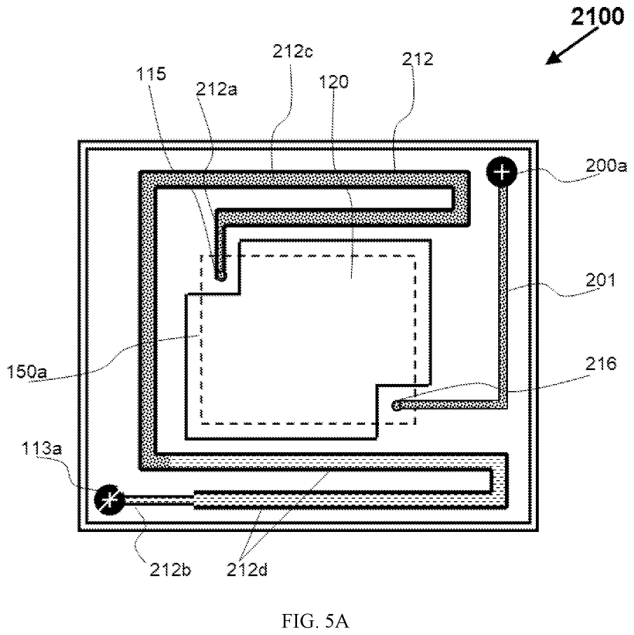

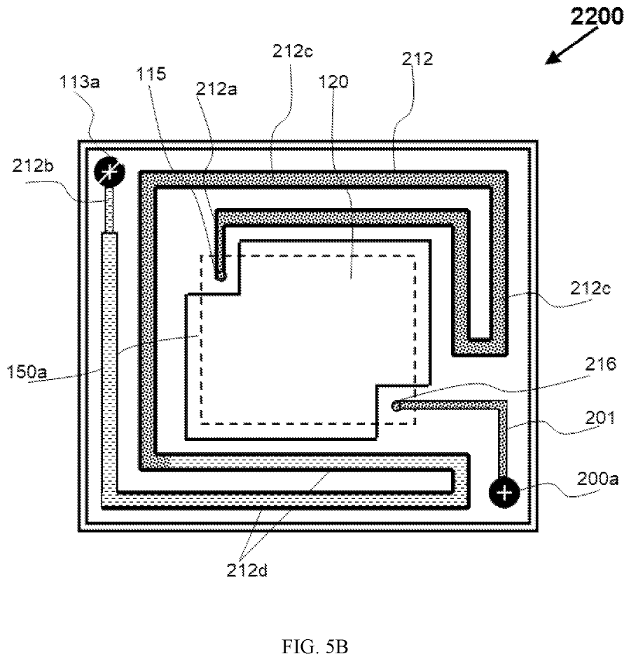

FIG. 5 to FIG. 5B are schematic diagrams for illustrating a preferred design for an injection hole of a lid allowing for a thermal interface material with fluidity in a lidded flip chip package of another preferred embodiment of the present disclosure, wherein an injection tunnel is introduced so that a plug structure at an outer end of the injection tunnel is used as an injection hole. It is seen that the injection hole 121 of the embodiments as shown in the previous drawings in FIG. 1 to FIG. 4 needs to be at a region directly above the flip chip and inside the sealing ring 103. An advantage of using an injection tunnel is that an injection hole can be flexibly designed so that it does not have to be directly above the flip chip and inside the sealing ring 103, but can be at any location, for example, at a corner location of the top piece and above the foot. The numerical symbol 2000 in FIG. 5 designates a cross-sectional view of a lidded flip chip package, in which the numerical symbols 200 and 200a designate a plug structure including a screw 200a in a screw hole 200 as an injection hole, which is arranged at a corner region of the lid and above the foot 102 so that the foot 102 can be further used for designing the plug structure, the numerical symbols 201 designates an injection tunnel which is formed in the ring-form cavity 110 as shown in FIG. 1 and is connected to the sealed gap through a connecting hole 216, the numerical symbol 212 designates a storage tunnel, the numerical symbols 212a and 212b designate two ends of the storage tunnel 212, and the 212c and 212d designate two portions of the storage tunnel 212, a portion 212c is filled with the same thermal interface material having fluidity as that in the sealed gap 130, and the remaining portion 112d is filled with a gas, the 212c and 212d also designate the thermal interface material having fluidity and the gas filled in the two portions, respectively. It is noted that since the storage tunnel 212 is also formed in the ring-form cavity 110, it needs to be rearranged to avoid crossing with the injection tunnel 201. An arrangement for the injection tunnel 201 and the storage tunnel 212 is described in FIG. 5A, in which the same numerical symbols as those in FIG. 5 designate the top views of the same elements, and are not repeatedly described. It is noted that a storage tunnel and an injection tunnel can be flexibly designed according to the sizes of a flip chip and a substrate of a flip chip package in a specific application, an example has been illustrated in FIG. 5A, and another example is illustrated in FIG. 5B, in which the same numerical symbols are used to designate the same elements, and are not repeatedly described. It is noted that the patterns for a storage tunnel and an injection tunnel can be flexibly designed, and a basic rule for designing the two tunnels is that the length of the storage tunnel needs to be designed so that its volume is big enough to accommodate the volume change of the sealed gap, while the injection tunnel is only for flexibly determining a location for the injection hole and its volume is not important. It is also noted that the width and depth of a storage tunnel are not limited to be uniform, but can be flexibly designed. For example, the storage tunnel can be designed thinner near its outer end so that it can be more easily closed by a plug structure.

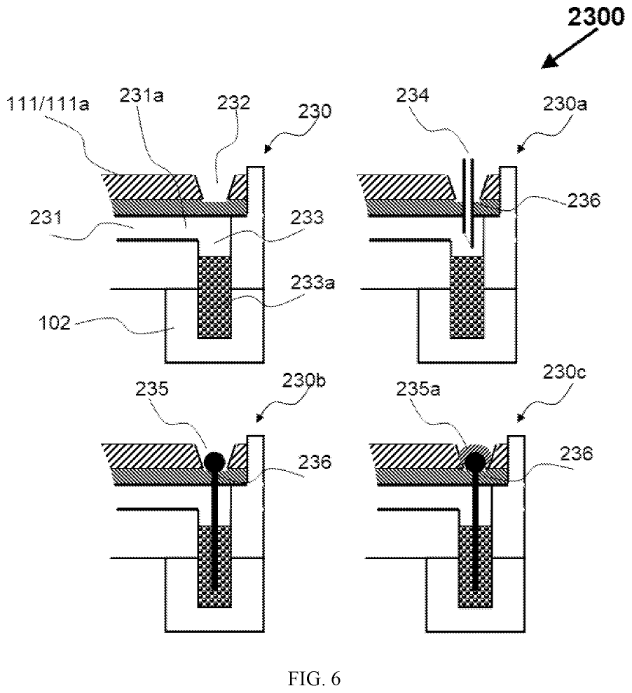

It is noted that some designs for a plug structure have been described previously in conjunction with the drawings in FIG. 1 to FIG. 4. Because a liquid metal and a gas is sealed in the sealed gap and the storage tunnel of a lidded flip chip package in its application as a preferred option, the reliability of a plug structure is also important in addition to its ease of usage. FIG. 6 is a schematic diagram for illustrating a preferred design for a plug structure for opening or closing a storage tunnel or an injection hole of a lid allowing for a lidded flip chip package to use a thermal interface material with fluidity of one preferred embodiment of the present disclosure. The numerical symbol 2300 in FIG. 6 designates a cross-sectional view of a plug structure, comprising: a hole extending down from the outer end of the storage or injection tunnel into the foot, a locking material arranged in a lower portion of the hole, and a pin with a head, wherein the pin goes through the covering piece with its tip portion being inserted into the locking material and its head being kept above the covering piece for sealing a tiny hole which is pre-formed through the covering piece or formed when the pin goes through the covering piece. The numerical symbol 2300 in FIG. 6 designates a cross-sectional view of a plug structure, in which the numerical symbol 230 designates a structure at an outer end 231a of a storage or injection tunnel 231, the 232 designates a point type of notch in a covering piece 111/111a as an option, the 233 designates a hole extending down from the outer end 231a into the foot 102, and 233a designates a locking material, like a rubber, arranged in a lower portion of the hole 233; the numerical symbol 230b illustrates a pin 235 with a head as a plug that goes through the covering piece 111/111a with its tip portion inserted into the locking material 233a and its head kept above the covering piece to seal a tiny hole 236 which is pre-formed in the covering piece 111/111a or formed when the pin goes through the covering piece 111/111a; the numerical symbol 230c illustrates that the head of the pin 235 also includes an adhesive layer 235a to better seal the tiny hole 236; and the numerical symbol 230a illustrates that after the pin 235 is removed to open the outer end 231a of the tunnel 231 to an ambient outside the lid, a syringe needle 234 can be inserted into the tiny hole 236 to inject a liquid if the plug structure is for an injection hole. It is noted that after the pin 235 is removed to open the outer end 231a of the tunnel 231 as a storage tunnel, a desired gas with a desired gas pressure can be arranged into a storage tunnel by setting an ambient condition, which will be further described below.

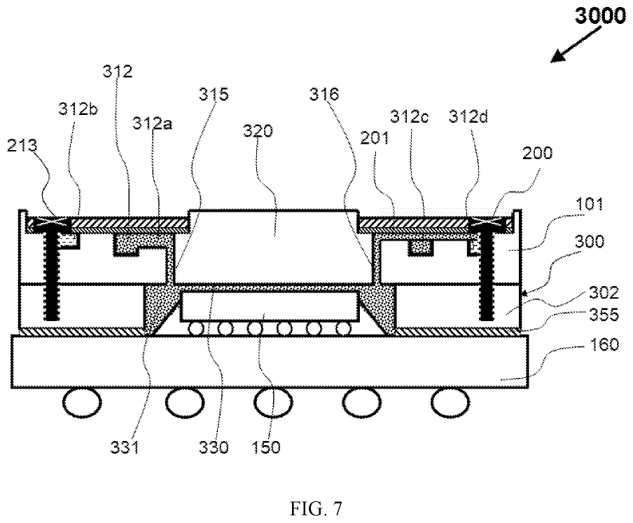

FIG. 7 is a schematic diagram for illustrating another preferred design for a sealing ring of a lidded flip chip package of one preferred embodiment of the present disclosure, wherein the foot is a ring-form of foot along a peripheral region at a lower side of the top piece, an adhesive is completely interposed between the foot and the substrate for bonding the lid on the substrate through the foot, the ring-form of foot with the adhesive also forms a sealing ring around the flip chip so as to form a sealed gap between the lid and the flip chip, and the sealed gap also includes a cavity around the flip chip and between the lid and the substrate. The numerical symbol 3000 in FIG. 7 designates a cross-sectional view of a lidded flip chip package of one preferred embodiment of the present disclosure, in which the numerical symbol 300 designates a sealing ring consisting of a ring-form of foot 302 and an adhesive 355 which is completely interposed between the foot 302 and the substrate 160 for bonding the lid on the substrate, the numerical symbols 330 and 331 designate a sealed gap between the top piece 101 of the lid and the flip chip 150, which also includes a cavity 331 around the flip chip 150, the numerical symbol 312 designates a storage tunnel, the numerical symbols 312a and 312b designate two ends of the storage tunnel 312, and the 312c and 312d designate two portions of the storage tunnel 312, a portion 312c is filled with the same thermal interface material having fluidity as that in the sealed gap 330 and 331, and the remaining portion 312d is filled with a gas, the 312c and 312d also designate the thermal interface material having fluidity and the gas filled in the two portions, the numerical symbols 201 and 200 designates an injection tunnel and a plug structure for an injection hole similar as those described in FIG. 5, the numerical symbol 315 designates a connecting hole for connecting the storage tunnel 312 with the sealed gap 330 and 331, and the numerical symbol 316 designates another connecting hole for connecting the injection tunnel 201 with the sealed gap 330 and 331. It is noted that a benefit to use a sealing ring outside the flip chip 150, like the foot 302 with the adhesive 355, is that the connecting holes 315 and 316 can be arranged not to be right above the flip chip 150, so that the island portion 320 of the top piece can be designed as large as possible and a plug structure 200 for an injection hole can be placed outside the island portion 320 so that it doesn't affect the heat dissipation from the flip chip to ambient.

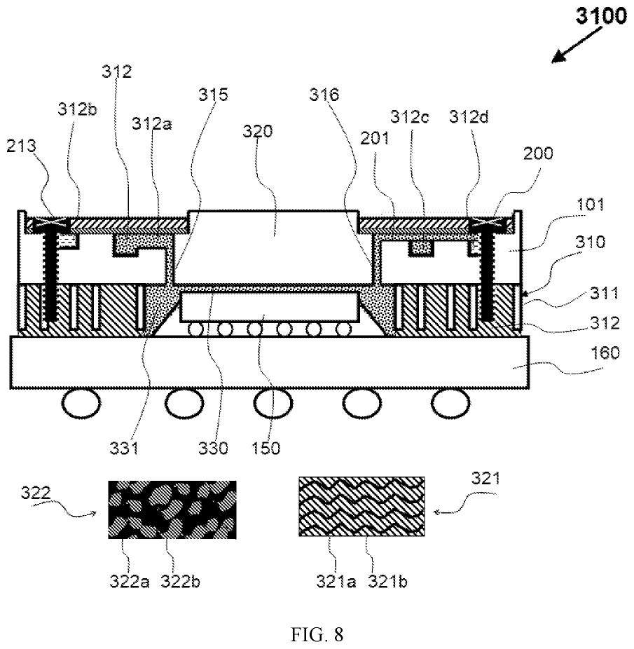

FIG. 8 is a schematic diagram for illustrating another preferred design for a foot of a lidded flip chip package of one preferred embodiment of the present disclosure, wherein the foot consists of a plurality of pins filled with an adhesive among them, a piece of porous material impregnated with an adhesive or resin, or a piece of mesh impregnated with an adhesive or resin. The numerical symbol 3100 in FIG. 8 designates a cross-sectional view of a lidded flip chip package of one preferred embodiment of the present disclosure, in which the numerical symbol 310 designates a foot consisting of a plurality of pins 311 filled with an adhesive or resin 312 among them, the adhesive or resin 312 is also used to bond the lid on the substrate, the numerical symbol 322 designates a foot consisting of a piece of porous material 322a impregnated with an adhesive or resin 322b, and the numerical symbol 321 designates a foot consisting of a piece of mesh 321a impregnated with an adhesive or resin 321b. It is noted that the various foot structures 310, 321 or 322 can be also used as a sealing ring as shown in FIG. 8 or only used as a foot to bond the lid on the substrate as shown in the previous drawings in FIG. 1 to FIG. 5.

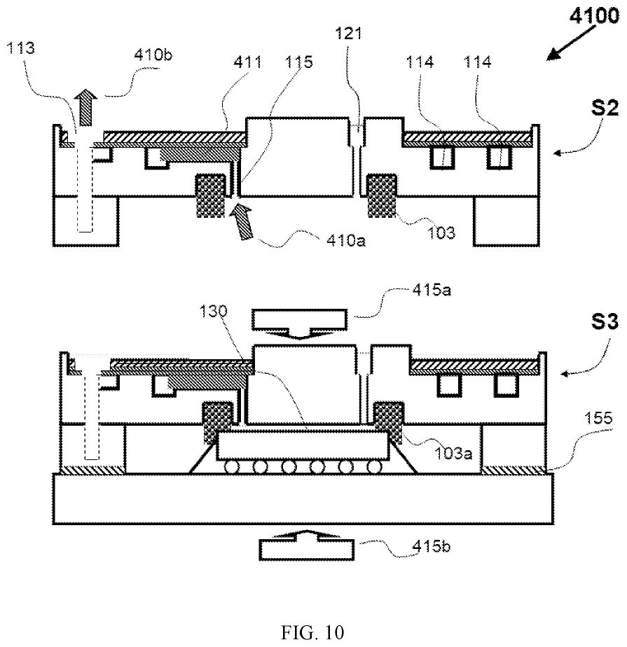

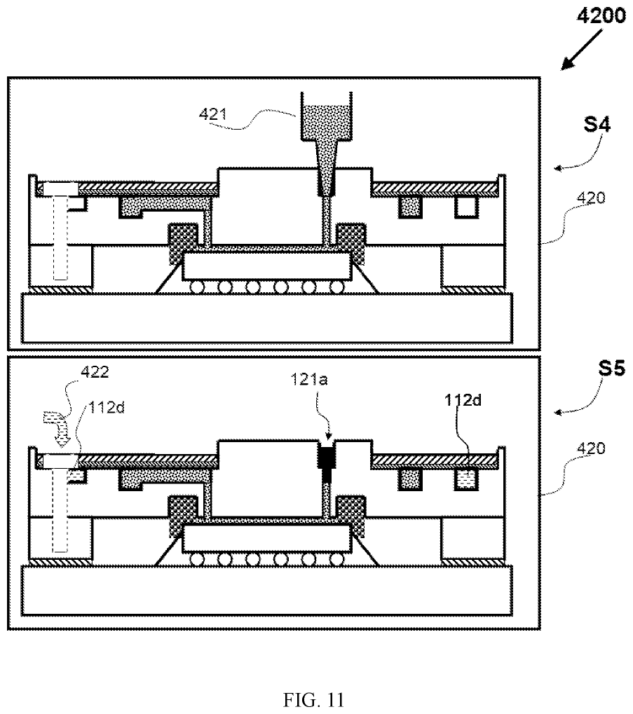

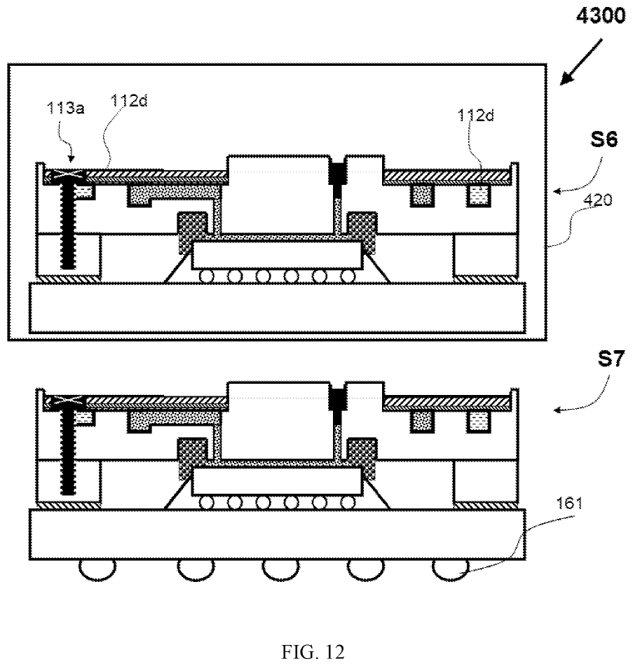

FIG. 9 to FIG. 12 are schematic diagrams for illustrating a method for making a lidded flip chip package as shown in FIG. 1A or similarly for making a lidded flip chip package as shown in FIG. 5, FIG. 7 or FIG. 8 of one preferred embodiment of the present disclosure. The method comprises the following major steps 1 to 7 as illustrated by FIG. 9 for Step 1, FIG. 10 for Steps 2 and 3, FIG. 11 for Steps 4 and 5, and FIG. 12 for Steps 6 and 7, which are described in the following:
The numerical symbols 4000 and S1 in FIG. 9 are for illustrating Step 1:
1) Prepare a lid 400 according to a flip chip package 401, the lid (referring to FIG. 1 and FIG. 1A for its description) includes: a top piece with an upper side and a lower side, a foot at the lower side of the top piece, a ring-form of cavity with a bottom at the upper side of the top piece, a covering piece, a storage tunnel as a reservoir, a plug structure 113/113a at an outer end of the storage tunnel, another plug structure including an injection hole 121 and a plug 121a, and a sealing ring; wherein the sealing ring is mounted at the lower side of the top piece; wherein a pattern of notch is formed at the bottom of the ring-form of cavity, and the covering piece is placed in the ring-form of cavity so as to cover the pattern of notch and form the storage tunnel; wherein a connecting hole has one end at the lower side of the top piece and inside the sealing ring, and has another end connected to one end of the storage tunnel; and wherein another end of the storage tunnel is mounted with the plug structure 113/113a;
The numerical symbols 4100 and S2 in FIG. 10 are for illustrating Step 2:
2) Open the storage tunnel and the injection hole by removing the plug 113a and the plug 121a respectively, and then fill an amount of lubricant oil 411 into the storage tunnel from the connecting hole 115, as illustrated by the arrow 410a, or use a lubricant oil to wash the storage tunnel from the connecting hole 115 as illustrated by the pair of arrows 410a and 410b so as to form a slippery skin 114 on an inner surface of the storage tunnel;
The numerical symbols 4100 and S3 in FIG. 10 are for illustrating Step 3:
3) Mount the lid on the substrate and over the flip chip, wherein an adhesive 155 is interposed between the foot and the substrate and a clamping force as illustrated by the pair of arrows 415a to 415b is applied so that the adhesive bonds the lid with the substrate at a curing temperature and the sealing ring 103a is tightly compressed to seal a peripheral edge region at a top surface of the flip chip and form a sealed gap 130 between the flip chip and the top piece of the lid;
The numerical symbols 4200 and S4 in FIG. 11 are for illustrating Step 4:
4) Put the assembly formed in Step 3 into a vacuum oven or container 420 and set it to a vacuum condition to degas the assembly, and then fill a liquid metal into the sealed gap and a portion of the storage tunnel from the injection hole, as illustrated by the syringe tip 421;
The numerical symbols 4200 and S5 in FIG. 11 are for illustrating Step 5:
5) Close the injection hole by putting back the plug 121a during vacuum condition first, and then put a desired gas with a desired gas pressure into the vacuum oven or container 420 to fill the remaining portion of the storage tunnel with the gas 112d, as illustrated by the arrow 422;
The numerical symbols 4300 and S6 in FIG. 12 are for illustrating Step 6:
6) Close the storage tunnel by putting back the plug 113a so that the gas 112d is sealed inside the storage tunnel;
The numerical symbols 4300 and S7 in FIG. 12 are for illustrating Step 7:
7) Mount solder balls 161 at a bottom side of the substrate so that a lidded flip chip package as illustrated in FIG. 1A is formed.

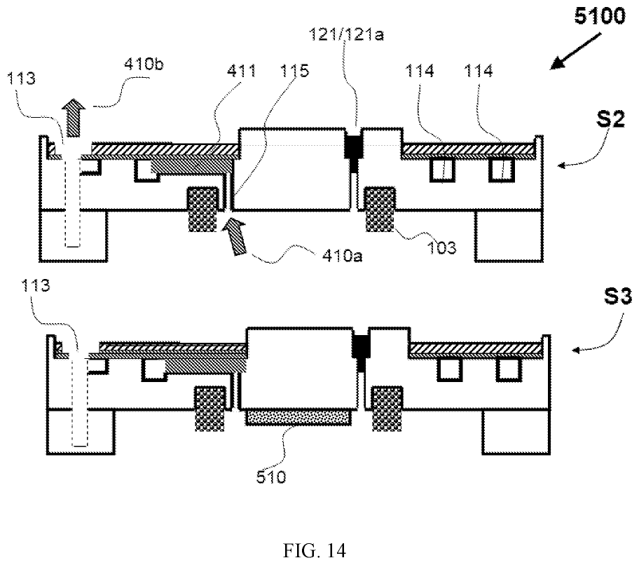

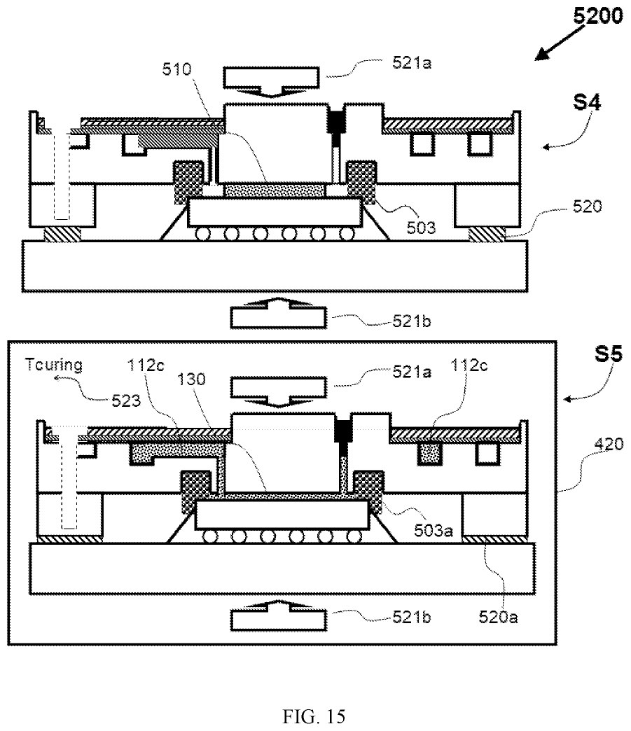

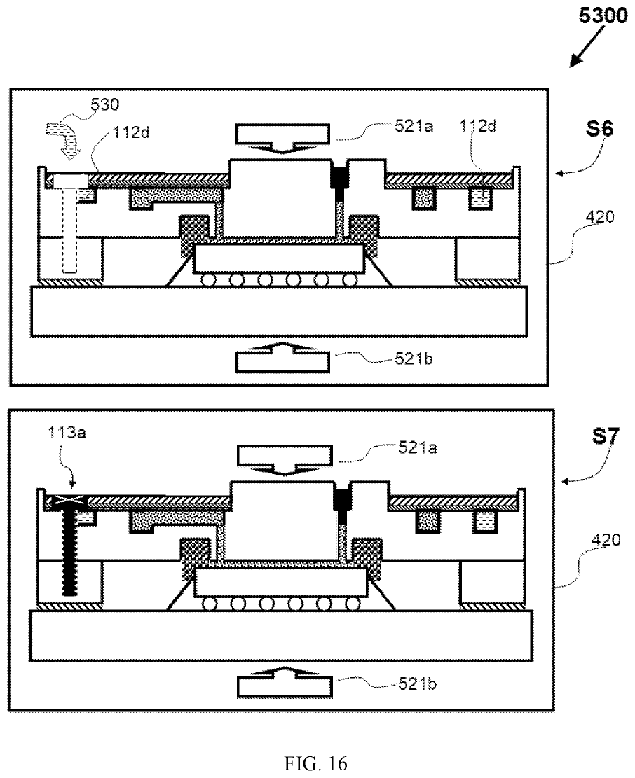

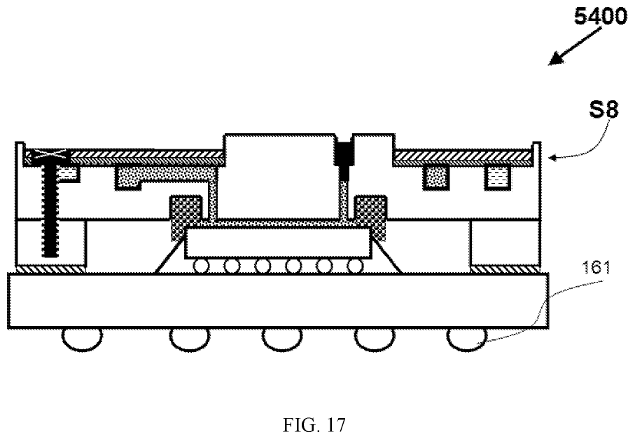

FIG. 13 to FIG. 17 are schematic diagrams for illustrating another method for making a lidded flip chip package as shown in FIG. 1A or similarly for making a lidded flip chip package as shown in FIG. 5, FIG. 7 or FIG. 8 of one preferred embodiment of the present disclosure. The method comprises the following major steps 1 to 8 as illustrated by FIG. 13 for Step 1, FIG. 14 for Steps 2 and 3, FIG. 15 for Steps 4 and 5, FIG. 16 for Steps 6 and 7, and FIG. 17 for Step 8, which are described in the following:
The numerical symbols 5000 and S1 in FIG. 13 are for illustrating Step 1:
1) Prepare a lid 400 according to a flip chip package 401, the lid (referring to FIG. 1 and FIG. 1A for its description) includes: a top piece with an upper side and a lower side, a foot at the lower side of the top piece, a ring-form of cavity with a bottom at the upper side of the top piece, a covering piece, a storage tunnel as a reservoir, a plug structure 113/113a at an outer end of the storage tunnel, another plug structure including an injection hole 121 and a plug 121a, and a sealing ring; wherein the sealing ring is mounted at the lower side of the top piece; wherein a pattern of notch is formed at the bottom of the ring-form of cavity, and the covering piece is placed in the ring-form of cavity so as to cover the pattern of notch and form the storage tunnel; wherein a connecting hole has one end at the lower side of the top piece and inside the sealing ring, and has another end connected to one end of the storage tunnel; and wherein another end of the storage tunnel is mounted with the plug structure 113/113a;
The numerical symbols 5100 and S2 in FIG. 14 are for illustrating Step 2:
2) Open the storage tunnel by removing the plug 113a, and then fill an amount of lubricant oil 411 into the storage tunnel from the connecting hole 115, as illustrated by the arrow 410a, or use a lubricant oil to wash the storage tunnel from the connecting hole 115 as illustrated by the pair of arrows 410a and 410b so as to form a slippery skin 114 on an inner surface of the storage tunnel;
The numerical symbols 5100 and S3 in FIG. 14 are for illustrating Step 3:
3) Attach a piece of preformed liquid metal pad 510 or form a liquid metal pad 510 at a bottom surface of the top piece and inside the sealing ring under a low temperature; wherein the liquid metal pad is in a solid state due to the low temperature;
The numerical symbols 5200 and S4 in FIG. 15 are for illustrating Step 4:
4) Clamp the lid formed in Step 3 onto the flip chip package prepared in the previous Step 1 using a clamping force as illustrated by the pair of arrows 521a and 521b, wherein an adhesive 520 is interposed between the foot of the lid and the substrate, the sealing ring 503 is compressed to seal at a peripheral edge region at a top surface of the flip chip and form a sealed gap between the lid and flip chip, and the liquid metal pad 510 is clamped between the lid and the flip chip and enclosed in the sealed gap;
The numerical symbols 5200 and S5 in FIG. 15 are for illustrating Step 5:
5) Put the assembly formed in Step 4 into a vacuum oven or container and set it at a vacuum condition to degas the assembly, and then raise the oven temperature above the melting point of the liquid metal and hold this temperature for a period of time until the liquid metal becomes molten, so that the seal ring is further compressed, the thickness of the sealed gap becomes thinner, the adhesive is compressed to spread to spread between the foot and the substrate, and the molten liquid metal pad is squeezed to fill the sealed gap and a portion of the storage tunnel; and then raise the oven temperature to a curing temperature of the adhesive and hold it until the adhesive becomes cured;
The numerical symbols 5300 and S6 in FIG. 16 are for illustrating Step 6:
6) Put a desired gas with a desired gas pressure as illustrated by the arrow 530 into the vacuum oven or container 420 to fill the remaining portion of the storage tunnel 112d with the gas;
The numerical symbols 5300 and S7 in FIG. 16 are for illustrating Step 7:
7) Close the storage tunnel by putting back the plug 113a so that the gas 112d is sealed inside the storage tunnel;
The numerical symbols 5400 and S8 in FIG. 17 are for illustrating Step 8:
8) Mount solder balls 161 at a bottom side of the substrate so that a lidded flip chip package as illustrated in FIG. 1A is formed.

It is noted that the step 2 for forming a slippery skin on an inner surface of the storage tunnel in the previously described methods for making a lidded flip chip package can be avoided if an inert gas is used in the storage tunnel. It is also noted that a benefit of using a plug structure at an outer end of the storage tunnel is that a desired gas, like an inert gas including nitrogen and helium, can be sealed in the storage tunnel to avoid an oxidation of a liquid metal in the storage tunnel, and the gas pressure can be designed to improve the flow of the liquid metal. Furthermore, even if a natural air is used in the storage tunnel, the oxygen will be quickly exhausted due to oxidation with the liquid metal in the storage tunnel, and the oxidation of the liquid metal will not accumulate to cause a severe issue. Another usage of a pair of plug structures for the injection hole and the storage tunnel is to withdraw out the liquid metal from the sealed gap and the storage tunnel by opening the storage tunnel and the injection hole, which may be needed when using a cross-sectional cut of the lidded flip chip package to perform a failure analysis. However, it is seen from the descriptions for the method illustrated in FIG. 13 to FIG. 17 that when a preformed liquid metal pad is used, the injection hole is not used for making the lidded flip chip package. So, if the liquid metal doesn't need to be withdrawn out from the sealed gap and the storage tunnel, the injection hole can be avoided.

It is noted that the plug structure for a lidded flip chip package to use a liquid metal thermal interface material described in the U.S. patent application Ser. No. 17/695,826, filed in Mar. 15, 2022 is not very convenient and reliable in its application, wherein the plug needs to be removed to fill a liquid metal into the sealed gap of the lidded flip chip package and then be put back afterwards under vacuum conditions. In the present application as a continuation-in-part of the previous U.S. patent application, a self-sealing plug structure is innovated and integrated with a storage tunnel and an injection tunnel of a lidded flip chip package so that a method to fill a liquid metal into the sealed gap of the lidded flip chip package can be easily performed under ambient conditions.

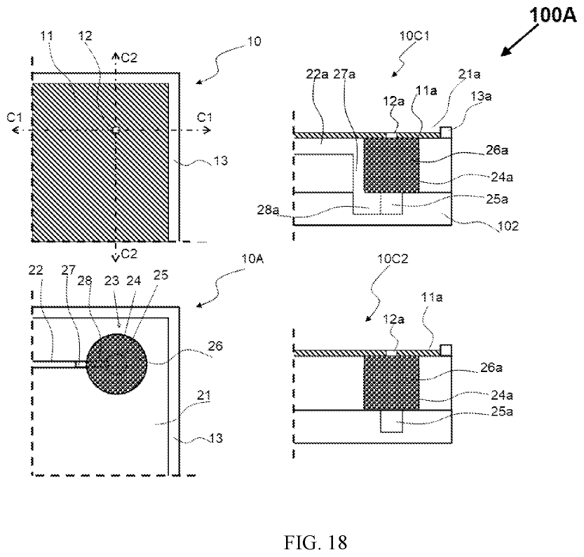

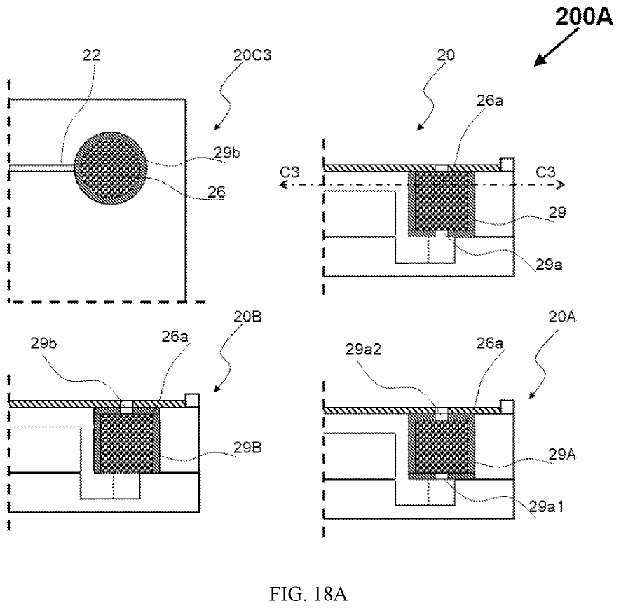

FIG. 18 is a schematic diagram for illustrating a self-sealing plug structure formed at an end of a tunnel for filling and sealing a liquid metal in a lidded flip chip package to form a liquid metal thermal interface material of one preferred embodiment of the present disclosure. The numerical symbol 100A in FIG. 18 designates top views and cross-sectional views of a self-sealing plug structure at a corner portion of a lid, referring to the drawing in FIG. 5 for a detailed description of the lid, which includes a plug structure with a screw, and herein a self-sealing plug structure is innovated to replaced the old plug structure. The numerical symbol 10 designates a top view of the self-sealing plug structure at the corner portion of the lid, in which the 11 designates a covering piece mounted in a ring-form of cavity on the upper side of the lid, the 12 designates a tiny hole through the covering piece for a needle to go through, and the 13 designates a rim of the ring-form of cavity, which can be an option, i.e. the rim can be removed, the arrow lines C1 and C2 designates two locations to make cross-sectional views for displaying the self-sealing plug structure further. The numerical symbol 10A in FIG. 18 designates a top view of the self-sealing plug structure at the corner portion of the lid after the covering piece 11 is removed to display its inner structure, in which the 21 designates a corner portion of the ring-form of cavity on the upper side of a lid, 22 designates an end portion of a tunnel, 23 designates a step-form of hole including an upper portion 24 and a lower portion 25, 26 designates a self-sealing block mounted in the upper portion 24 and underneath the covering piece 11, 27 and 28 respectively designate a notch extending down from an end of the tunnel 22 and a notch extending from a bottom of the notch 27 to the lower portion 25 of the step-form of hole 23 so that a connecting hole is formed by the two notches 27 and 28 and the self-sealing block 26, which connects the tunnel 22 with the lower portion 25 of the step-form of hole 23. The numerical symbol 10C1 in FIG. 18 designates a cross-sectional view along C1 as shown in the top view 10 of the self-sealing plug structure at the corner portion of the lid, in which the 11a, 12a and 13a designate the cross-sectional views of the covering piece 11, the tiny hole 12, and the rim 13 in the top view 10, the 21a designates the cross-sectional view of the corner portion of the ring-form of cavity 21 in the top view 10a, the 22a designates the cross-sectional view of the end portion of a tunnel 22 in the top view 10a, the 24a and 25a designate the cross-sectional view of the upper portion 24 and the lower portion 25, 26a designates the cross-sectional view of the self-sealing block 26 mounted in the upper portion 24a and underneath the covering piece 11a, the 27a and 28a designate the notch 27 extending down from an end of the tunnel 22a and the notch extending from a bottom of the notch 27a to the lower portion 25a of the step-form of hole 23 so that the tunnel 22a is connected with the lower portion 25a of the step-form of hole 23 through the notches 27a and 28a, and the 102 designate a foot of the lid (referring to FIG. 5), into which the lower portion 25a of the step-form of hole 23 is formed when the top piece of the lid is not thick enough. The numerical symbol 10C2 in FIG. 18 designates a cross-sectional view along C2 to C2 as showed in the top view 10 of the self-sealing plug structure at the corner portion of the lid, in which the 11a and 12a designate the cross-sectional views of the covering piece 11 and the tiny hole 12 in the top view 10, the 24a and 25a designate the cross-sectional view of the upper portion 24 and the lower portion 25, 26a designates the cross-sectional view of the self-sealing block 26 mounted in the upper portion 24a and underneath the covering piece 11a.

It is noted that a rubber material is preferred to make the self-sealing block 26a. To safely seal an end portion of a tunnel, the size of a rubber block is preferred to be bigger than the upper portion 24a of the step-form of hole so that it is tightly locked in the upper portion 24a. However, one concern is that the rubber material may be squeezed into the small notches 27a or 28a. To avoid this concern, a rubber block enclosed with a shell is used as a self-sealing block of a self-sealing plug structure of one preferred embodiment of the present disclosure. FIG. 18A is a schematic diagram for illustrating such a self-sealing plug structure, in which the numerical symbol 200A designates cross-sectional and top views of a self-sealing plug structure, including a rubber block enclosed with a shell, the 20 designates a cross-sectional view of a self-sealing plug structure with a cup-form of shell 29 for enclosing a rubber block 26, and the 29a designates a tiny hole at the bottom of the cup-form of shell 29 for a needle to go through and reach the lower portion 25a of the step-form of hole. The numerical symbol 20C3 in FIG. 18A designates a top view at the cross-section along the arrow line C3 as shown in the cross-sectional view 20 to further describe the cup-form of shell 29, in which the 29b shows a top view of the cup-form of shell 29, which prevents the rubber block 26 from being squeezed into the tunnel 22. The numerical symbol 20A in FIG. 18A designates a cross-sectional view of a self-sealing plug structure, in which the 29A designates a shell, which completely encloses the rubble block 26a except for two tiny holes 29a1 and 29a2 respectively at its bottom and top for a needle, which allow a needle to go through and reach the lower portion 25a of the step-form of hole. The numerical symbol 20B in FIG. 18A designates a cross-sectional view of a self-sealing plug structure, in which the 29B designates a flipped cup-form of shell, and the 29b designates a tiny hole at the bottom of the flipped cup-form of shell 29B for a needle to go through and reach the lower portion 25a of the step-form of hole. It is noted that the rubber plug does not necessarily need to completely fill the shell/cup/upper portion, and is merely illustrated as such as a preferred option.

FIG. 19 is a schematic diagram for further illustrating the self-sealing plug structure as described in FIG. 18 by displaying a liquid flow when filling a liquid through the plug into the tunnel. The numerical symbol 300A in FIG. 19 designates a way to fill and seal a liquid in a tunnel of a lid through the self-sealing plug structure, in which the 30a illustrates inserting a needle 31 of a liquid dispenser 32 through the self-sealing block 26a from the tiny hole 12a in the covering piece 11a and into the lower portion 25a of the step-form of hole first, such that the liquid can be injected; the 30b and arrow 33 illustrates that the liquid fills the lower portion 25a through the needle 31 first, the 30c and arrow 34 illustrate that the liquid further fills the notch 28a, and the 30d and 35 illustrate that the liquid fills the tunnel 22a and the self-sealing block gets closed after the needle 31 is removed.

It is noted that a rubber material is preferred to make the self-sealing block, which can seal itself after inserting a needle through it and then removing the needle. The self-sealing block based on a rubber material is preferred to be bigger than the upper portion of the step-form of hole so that it is tightly locked in the upper portion of the step-form of hole. Furthermore, a thin layer of glue can be applied on the surface of the self-sealing block first, after which it is mounted in the upper portion of the step-form of hole.

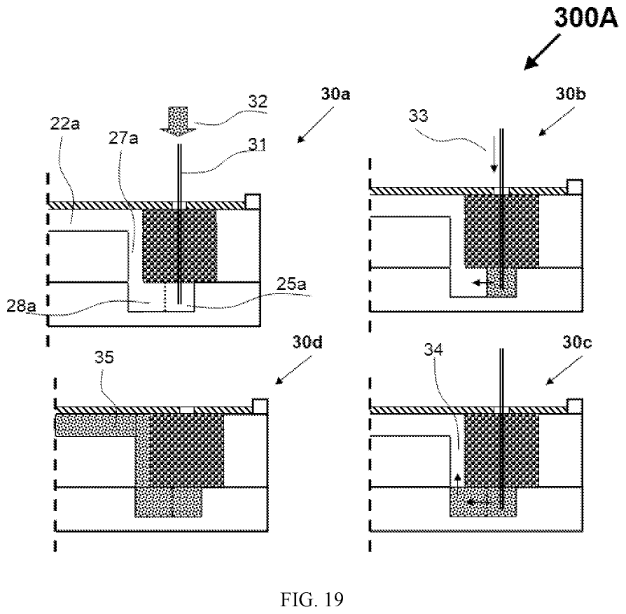

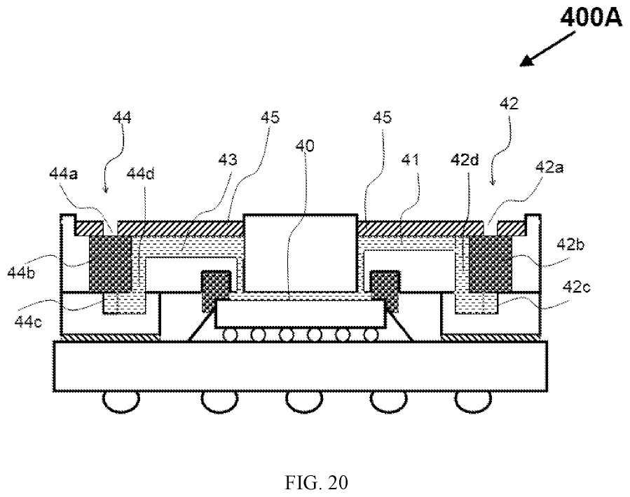

FIG. 20 to FIG. 29 are schematic diagrams for illustrating a method for filling a liquid metal into the sealed gap and a portion of the storage tunnel, and then filling a desired gas with a desired gas pressure, like an inert gas with a half of the atmosphere air pressure, into the remaining portion of the storage tunnel to form a lidded flip chip package with a liquid metal TIM based on the present self-sealing plug structure of another preferred embodiment of the present disclosure. The numerical symbol 400A in FIG. 20 designates a lidded flip chip package based on a lid with a self-sealing plug structure, wherein a liquid metal is ready to be filled, in which the numerical symbol 40 designates the sealed gap between the lid and the flip chip, the 41 and 43 designate an injection tunnel and storage tunnel in the lid, the 42 and 44 designate two self-sealing plug structures, one for the injection tunnel 41 and another for the storage tunnel 43, the 45 designates a ring-form of covering piece for forming the injection tunnel and the storage tunnel, which also locks the self-sealing blocks 42b and 44b inside the upper portions of the step-form of holes, the 42c and 44c designate the lower portions of the step-form of holes for the injection tunnel and the storage tunnel, and the 42d and 44d designate the connecting holes for connecting the injection tunnel and the storage tunnel with the lower portions 42c and 44c of the step-form of holes, respectively.

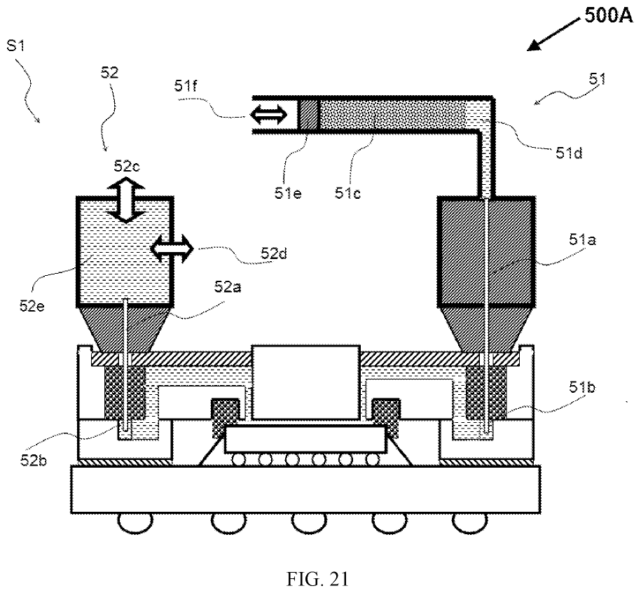

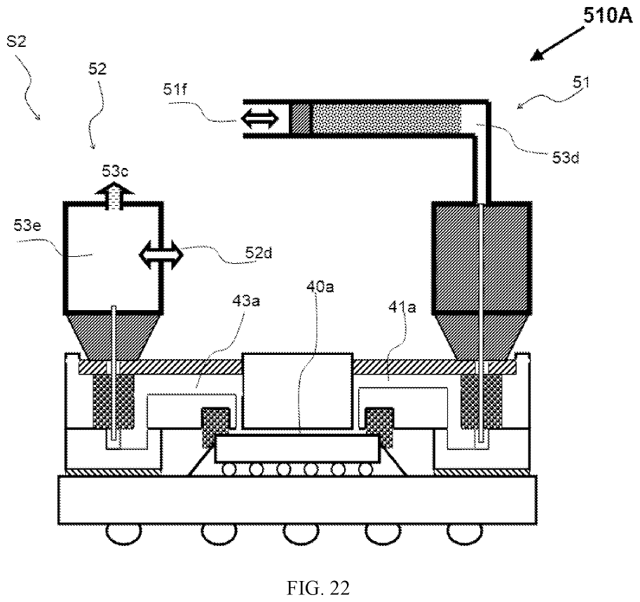

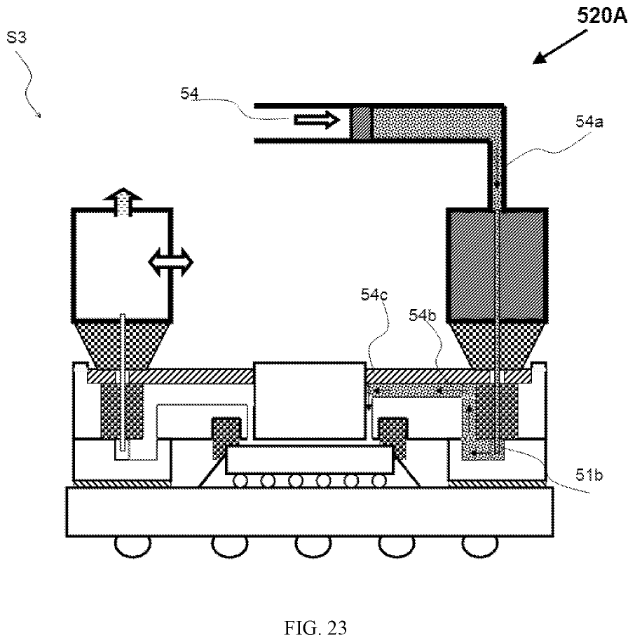

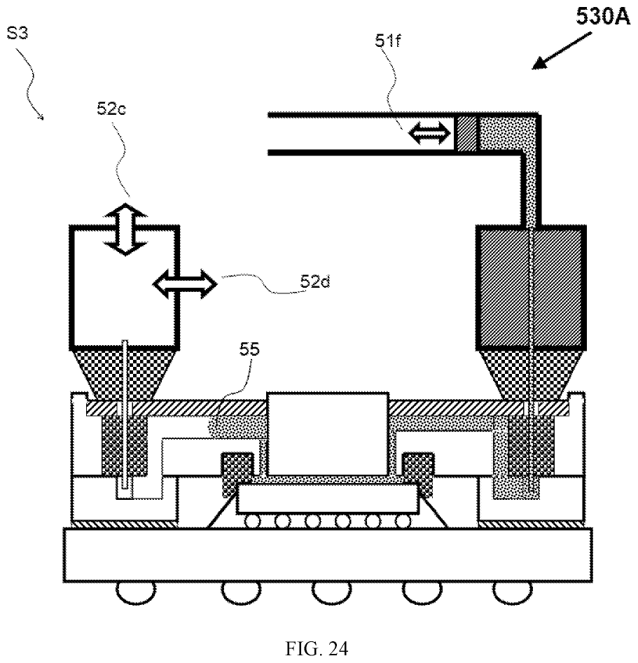

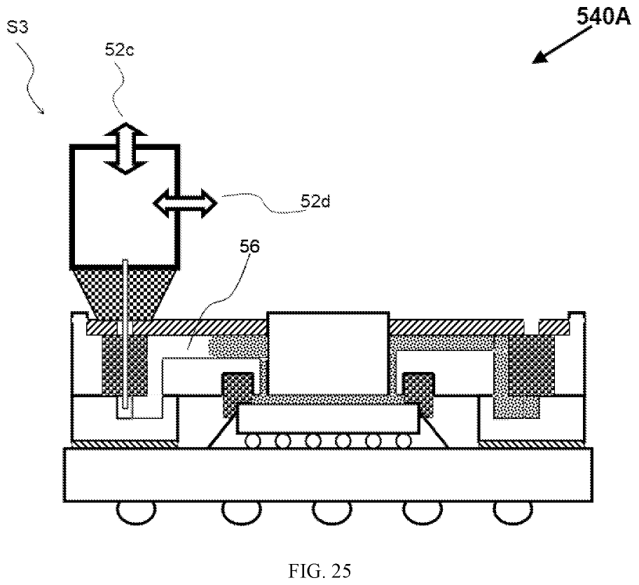

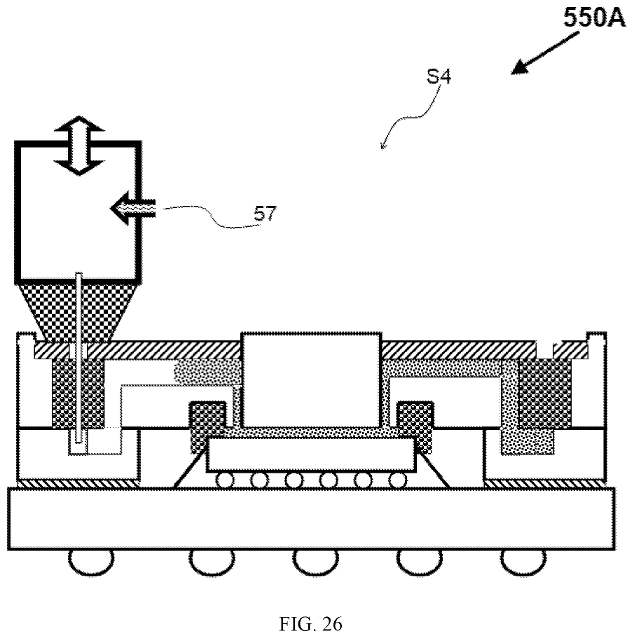

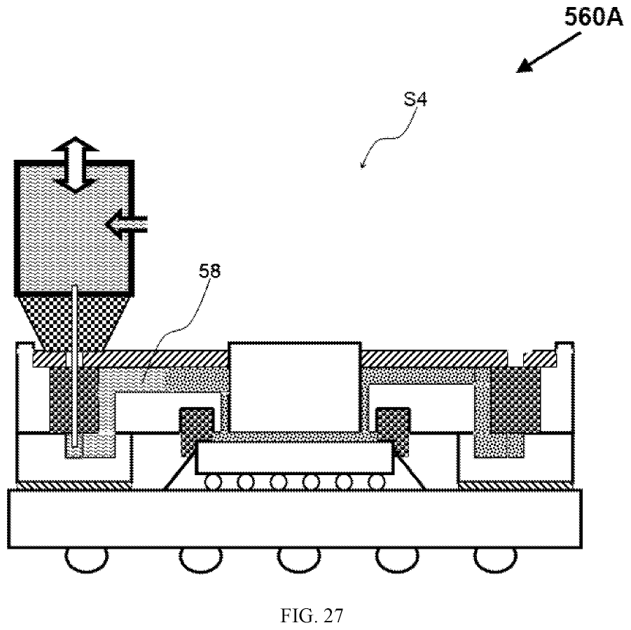

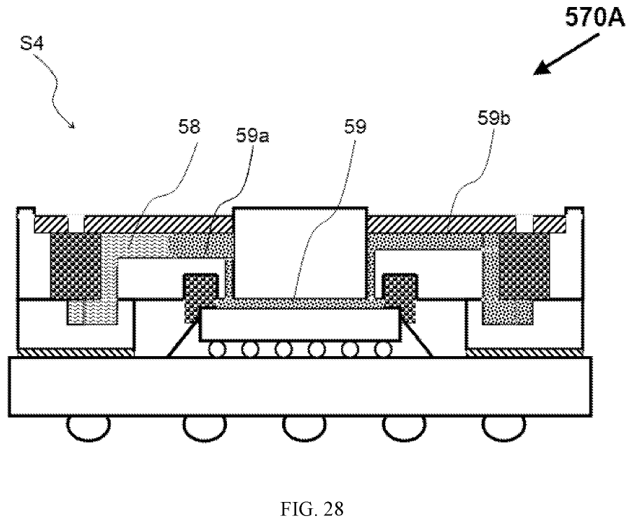

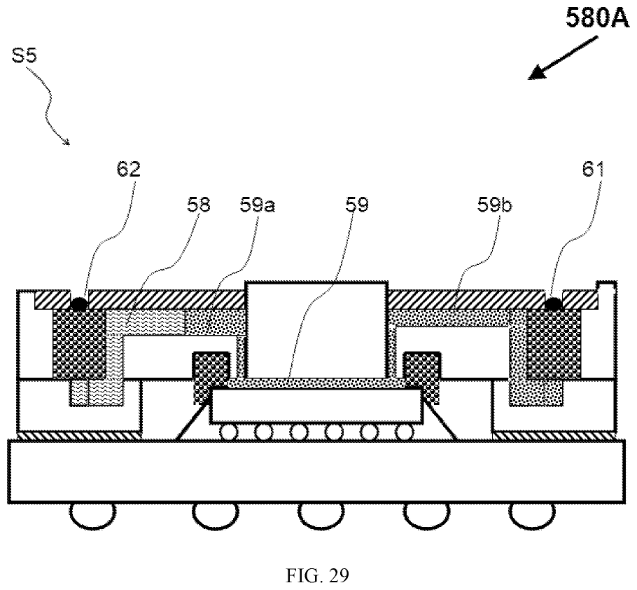

FIG. 21 to FIG. 29 are schematic diagrams for illustrating a method for filling a liquid metal into the lidded flip chip package 400A, mainly comprising the following steps:
The numerical symbols 500 and S1 in FIG. 21 are for illustrating Step 1:
1) Prepare a liquid metal dispenser 51, which includes a needle 51a with a tip 51b, a liquid metal container 51c with a piston 51e, and a moving controller 51f for controlling the movement of the piston 51e, and insert the needle tip 51b to the lower portion of the step-hole of the self-sealing plug structure for the injection tunnel; and prepare a vacuum pump tool 52, which includes a needle 52a with a tip 52b, a vacuum pump 52c, a gas filling switch 52d and a chamber 52e, and insert the needle tip 52b to the lower portion of the step-hole of the self-sealing plug structure for the storage tunnel;
The numerical symbols 510 and S2 in FIG. 22 are for illustrating Step 2:
2) Pump out the air in the entire system, including the lidded flip chip package, the liquid metal dispenser 51 and the vacuum pump tool 52 to achieve a vacuum condition, including the sealed gap 40a, the injection tunnel 41a, the storage tunnel 43a, the chamber 53e of the vacuum pump tool 52 and the tube 53d of the liquid metal dispenser 51;
The 520/530/540 and S3 in FIG. 23 to FIG. 25 are for illustrating Step 3:
3) Push the piston 51e as showed by the arrow 54 in FIG. 23 to fill the liquid metal from the needle tip 51b into first the injection tunnel, then the sealed gap, and finally a portion of the storage tunnel, as shown by the arrows 54a, 54b and 54c in FIG. 23 that illustrate the flow of the liquid metal, until a designed amount of liquid metal is filled into the lidded flip chip package, wherein a portion of the storage tunnel is filled with the liquid metal as shown by the numerical number 55 in FIG. 24; stop pushing the piston 51e, as shown by the arrow 51f, close the vacuum pump, as shown by the arrow 52c, and then remove the needle of the liquid metal dispenser from the self-sealing plug structure for the injection tunnel, as shown in FIG. 25, in which the numerical symbol 56 designates that the remaining portion of the storage tunnel is at vacuum condition at this point;
The 550/560/570 and S4 in FIG. 26 to FIG. 28 are for illustrating Step 4:
4) Open the gas filling switch of the vacuum pump, as shown by the arrow 57 in FIG. 26, to fill a desired gas into the remaining portion of the storage tunnel until a desired gap pressure in the remaining portion of the storage tunnel is achieved, as shown by the numerical symbol 58 in FIG. 27, and then close the gas filling switch and remove the needle of the vacuum pump tool from the self-sealing plug structure for the storage tunnel to get a lidded flip chip package with a liquid metal TIM, as shown by the numerical symbol 570 in FIG. 28;
The numerical symbols 580 and S5 in FIG. 29 are for illustrating Step 5:
5) Put a drop of adhesive or glue 61 and 62 in each hole of the covering piece associated with the self-sealing plug structures for the injection tunnel and the storage tunnel respectively for achieving a safer sealing.

It is noted that the self-sealing block is a critical part for the self-sealing plug structure. Its dimensions relative to the step-hole and its material selection need to be optimized. To achieve a safe and secure seal, the self-sealing block can be coupled with a layer of adhesive or glue on its surface so that it can bond with a surface of the step-form of hole or a surface of the covering piece.

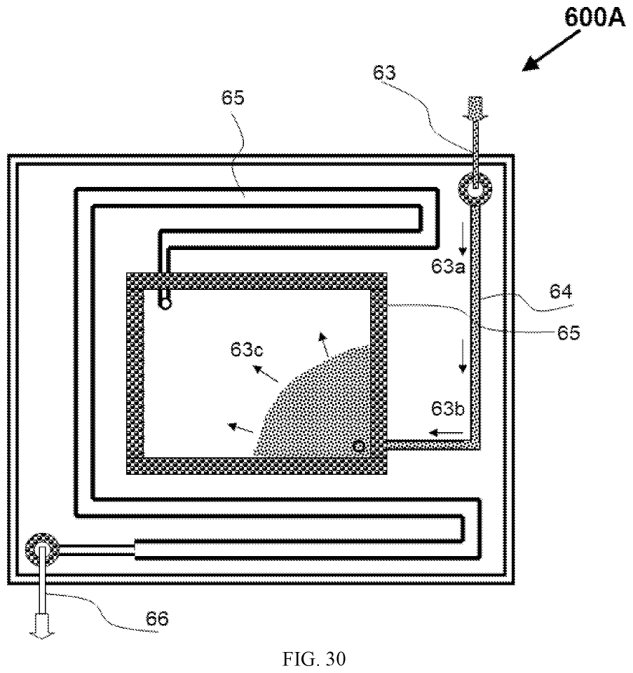

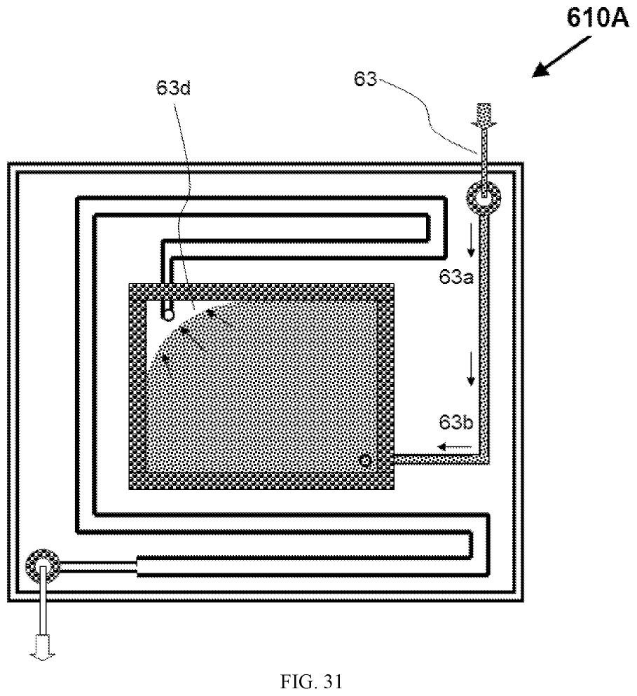

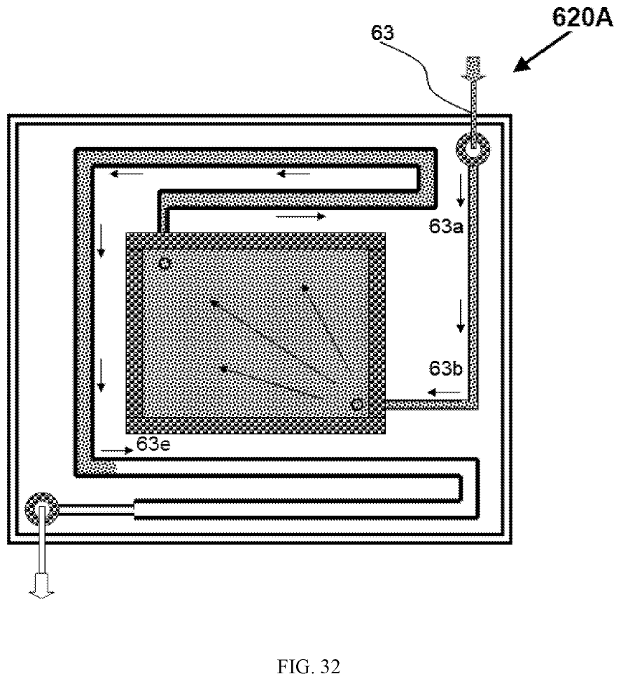

FIG. 30 to FIG. 32 are schematic diagrams for illustrating the flow of a liquid metal from its top view when filling it from the injection tunnel into the sealed gap and then into a portion of the storage tunnel. The numerical symbol 600 in FIG. 30 designates a top view of the flow of a liquid metal from injection tunnel to the sealed gap, in which the 63 designates a needle of a liquid metal dispenser, from which a liquid metal is filled into the injection tunnel, the 63a, 63b and 63c illustrate the flow of the liquid metal into the sealed gap, the 64 designates the injection tunnel, the 65 designates the storage tunnel, and the 66 designates a needle from a vacuum pump; the numerical symbol 610 in FIG. 31 designates a top view of the further flow of the liquid metal in the sealed gap, in which the 63d illustrates that the liquid metal flows towards the connecting hole and into the storage tunnel; the numerical symbol 620 in FIG. 32 designates a top view of the further flow of the liquid metal into the storage tunnel, in which the 63e illustrates that a portion of the storage tunnel has been filled.

FIG. 30 to FIG. 32 describes an ideal flow of the liquid metal when filling it from the injection tunnel into the sealed gap and then into a portion of the storage tunnel. However, an abnormal flow of the liquid metal may occasionally happen because the thickness of the sealed gap across the area of the flip chip is not uniform, i.e, the gap along the edge of the sealed gap may be thicker than that at its middle region due to the warpage behavior of the flip chip.

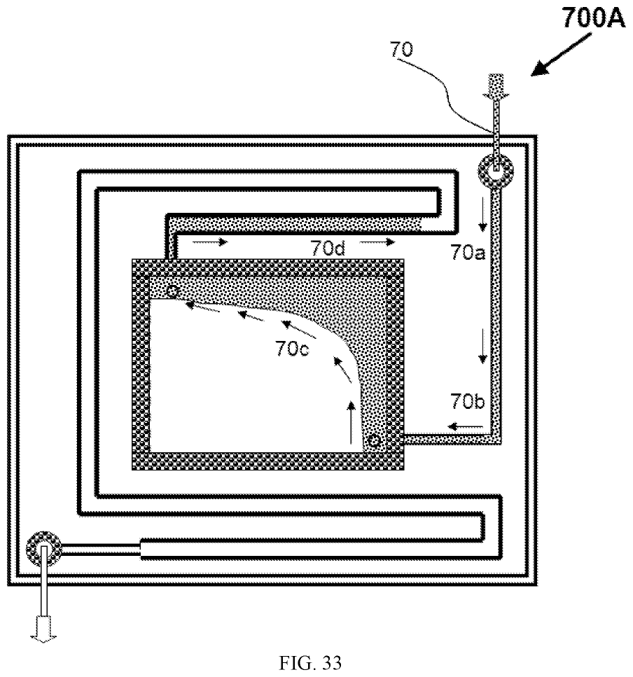

FIG. 33 is a schematic diagram for illustrating an abnormal flow of the liquid metal, in which the numerical symbols 70, 70a, 70b, 70c and 70d illustrate a flow of the liquid metal when filling it from the injection tunnel into the sealed gap and a portion of the storage tunnel. As a result, the liquid metal may fully fill the storage tunnel and even flow out from another step-form of hole at the outer end of the storage tunnel before completely filling the sealed gap.

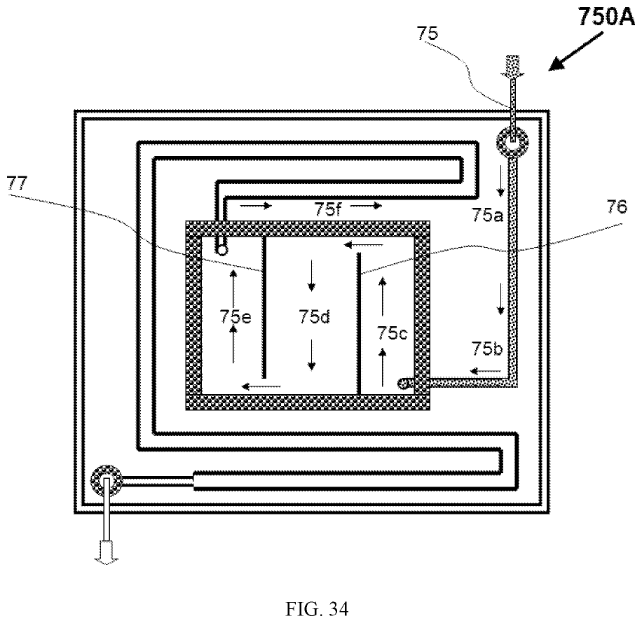

FIG. 34 is a schematic diagram for illustrating a way to avoid this abnormal flow, in which a plurality of guiding lines are introduced in the sealed gap to guide the flow of the liquid metal. The numerical symbols 76 and 77 designate two guiding lines so that the liquid metal is forced to flow according to a desired path as illustrated by the arrows 75a, 75b, 75c, 75d, 75e and 75f. It is noted that the number and shape of the guiding lines can be flexibly designed according to a specific application, and two guiding lines in FIG. 34 are displayed as an example.

It is noted that even though a self-sealing plug structure is described in FIG. 18, FIG. 18A and FIG. 19 and its application is described according to the lidded flip chip package as shown in figures from FIG. 20 to FIG. 34, it is apparent that it can be combined with one or more features previously described in conjunction with the drawings in figures from FIG. 1 to FIG. 17.

Although the present disclosure is described in some details for illustrative purposes with reference to the specific embodiments and drawings, it is apparent that many other modifications and variations may be made without departing from the spirit and scope of the present invention.

What is claimed is:

1. A lid allowing for a thermal interface material with fluidity in a lidded flip chip package, comprising:
a top piece with an upper side and a lower side, a foot at the lower side of the top piece, a storage tunnel as a reservoir, an injection tunnel, a sealing ring, and a self-sealing plug structure;
wherein the sealing ring is mounted at the lower side of the top piece, which seals a peripheral edge region at a top surface of a flip chip and/or seals a peripheral region around a flip chip and at a top surface of a substrate so as to form a sealed gap between the flip chip and the top piece;
wherein the lid further includes a ring-form of cavity at the upper side of its top piece, an island as a portion of the top piece which is surrounded by the ring-form of cavity, a pattern of notches which are formed at a bottom of the ring-form of cavity, and a covering piece mounted in the ring-form of cavity so as to cover the pattern of notches and form the storage tunnel and the injection tunnel;
wherein the storage tunnel has two ends, one end, called inner end herein of the said two ends connects to the sealed gap through a connecting hole, and the other end, called outer end herein of the said two ends includes a step-form of hole, which consists of an upper portion and a lower portion;
wherein the injection tunnel has two ends, one end, called inner end herein of the said two ends connects to the sealed gap through a connecting hole, and the other end, called outer end herein of the said two ends includes a step-form of hole, which consists of an upper portion and a lower portion;
wherein the self-sealing plug structure includes a self-sealing block and a step-form of hole; and
wherein the sealed gap is completely filled with a thermal interface material having fluidity, a portion of the storage tunnel is filled with the same thermal interface material, and the remaining portion of the storage tunnel is filled with a gas.

2. The lid of claim 1, wherein the self-sealing block is a rubber block.

3. The lid of claim 1, wherein the self-sealing block is a rubber block with a layer of adhesive or glue.

4. The lid of claim 1, wherein the self-sealing block consists of a rubber block enclosed with a shell.

5. The lid of claim 1, wherein the lid further includes a ring-form of notch at the lower side of the top piece, in which the sealing ring is mounted.

6. The lid of claim 1, wherein the lid further includes a slippery skin formed on an inner surface of the storage tunnel.

7. The lid of claim 1, wherein one or more filters are arranged adjacent to one or more openings through an adhesive layer.

8. The lid of claim 1, wherein the covering piece is a metal sheet mounted in the cavity through an adhesive layer.

9. The lid of claim 1, wherein the covering piece consists of a plurality of layers of metal foils.

10. The lid of claim 1, wherein the lidded flip chip package further includes a thermal conductive mesh in the sealed gap.

11. The lid of claim 1, wherein the lidded flip chip package further includes a plurality of guiding lines in the sealed gap.

12. The lid of claim 1, wherein the thermal interface material with fluidity is a liquid metal, including gallium and its alloys.

13. The lid of claim 1, wherein the gas in the storage tunnel is an inert gas, including nitrogen and helium.

14. The lid of claim 1, wherein the slippery skin is a layer of lubricant silicone oil or a layer of coating.

15. The lid of claim 1, wherein the foot consists of a plurality of pins filled with an adhesive among them, a piece of porous material impregnated with an adhesive or resin, or a piece of mesh impregnated with an adhesive or resin.

16. The lid of claim 1, wherein the foot is a ring-form of foot, an adhesive is interposed between the foot and the substrate for mounting the lid on the substrate, and the ring-form of foot with the adhesive is also the sealing ring for forming the sealed gap.

17. The lid of claim 16, wherein the foot consists of a plurality of pins filled with an adhesive among them, or a piece of porous material or mesh impregnated with an adhesive or resin.

18. A method for forming a liquid metal thermal interface material in the lidded flip chip package of claim 1: mainly comprising the following steps:
1) Prepare a lidded flip chip package, wherein the lid includes a self-sealing plug structure;
2) Insert a needle of a vacuum pump tool into the self-sealing plug structure for the storage tunnel, and insert a needle of a liquid metal dispenser into the self-sealing plug structure for the injection tunnel;
3) Pump out the air in the whole system, including the sealed gap, the storage tunnel and the injection tunnel of the lidded flip chip package;
4) Inject the liquid metal into the sealed gap and a portion of the storage tunnel from the needle of the liquid metal dispenser, and then remove the needle of the liquid metal dispenser;
5) Switch the vacuum pump to its gas filling state and fill a gas into the remaining portion of the storage tunnel, and then remove the needle of the vacuum pump tool.

19. The method of claim 18, wherein it further comprises the following step:
6) Put an adhesive or glue in one or more holes of the covering piece.
